(19) United States
(12) Patent Application Publication
(10) Pub. No.: US 2025/0221201 A1
(43) Pub. Date: Jul. 3, 2025

(54) DISPLAY SUBSTRATE AND DISPLAY APPARATUS

(71) Applicants: Hefei BOE Joint Technology Co.,Ltd., Hefei, Anhui (CN); BOE Technology Group Co., Ltd., Beijing (CN)

(72) Inventors: Jianwei YU, Beijing (CN); Zhidong YUAN, Beijing (CN); Yongqian LI, Beijing (CN)

(21) Appl. No.: 18/850,066

(22) PCT Filed: Feb. 18, 2024
(86) PCT No.: PCT/CN2024/077397

§ 371 Date: Sep. 24, 2024

(30) Foreign Application Priority Data
Mar. 15, 2023 (CN) 202310267768.4

(51) Int. Cl. H10K 59/131

(52) U.S. Cl. CPC H10K 59/131

(57) ABSTRACT

A display substrate and a display apparatus are provided. The display substrate includes a display area and a bonding area connected to the display area. The display area includes multiple data signal lines extending in a second direction, multiple first transfer connection electrodes extending in a first direction, multiple third transfer connection electrodes extending in the second direction, and multiple sub-pixels arranged in an array, at least some of the first transfer connection electrodes are respectively connected to the multiple data signal lines and are respectively connected to at least some of the third transfer connection electrodes, and the end of each third transfer connection electrode connected to a first transfer connection electrode is connected to the bonding area; lengths of the multiple data signal lines, which extend in the second direction, are not exactly the same; and the multiple sub-pixels form a plurality of pixels arranged in an array.

### CROSS-REFERENCE TO RELATED APPLICATIONS

The present application is a U.S. National Phase Entry of International Application PCT/CN2024/077397 having an international filing date of Feb. 18, 2024, claims priority to Chinese patent application No. 202310267768.4, filed to CNIPA on Mar. 15, 2023 and entitled “Display Substrate and Display Apparatus”, contents of which should be interpreted as being incorporated into the present application by reference.

### TECHNICAL FIELD

Embodiments of the present disclosure relate to, but are not limited to, the field of display technologies, and particularly relate to a display substrate and a display apparatus.

### BACKGROUND

With the rapid development of display technologies, special-shaped display apparatuses have gradually occupied the market. Emergence of special-shaped display apparatuses breaks through the limitation of single rectangular structure of display apparatuses, which makes the application of special-shaped display apparatuses more and more extensive. For example, currently, special-shaped display apparatuses have been widely used in fields such as smart wearable devices, smart vehicles.

### SUMMARY

The following is a summary of subject matter described herein in detail. This summary is not intended to limit the protection scope of claims.

In one aspect, the present disclosure provides a display substrate including a display area and a bonding area connected to the display area, wherein the display area includes a plurality of data signal lines extending in a second direction, a plurality of first transfer connection electrodes extending in a first direction, a plurality of third transfer connection electrodes extending in the second direction, and a plurality of sub-pixels arranged in an array, the plurality of data signal lines are respectively connected to a plurality of columns of sub-pixels, and the data signal lines, the first transfer connection electrodes, and the third transfer connection electrodes are respectively provided in three conductive layers.

At least a part of the first transfer connection electrodes are respectively electrically connected to the plurality of data signal lines and are respectively electrically connected to at least a part of the third transfer connection electrodes, and one ends of the third transfer connection electrodes connected to the at least part of the first transfer connection electrodes are electrically connected to the bonding area. In the display area, the lengths of the plurality of data signal lines along the second direction are not the same.

The plurality of sub-pixels form a plurality of pixels arranged in an array, one pixel includes at least three adjacent sub-pixels, and arrangement modes of a plurality of first transfer connection electrodes and a plurality of third transfer connection electrodes located in two pixels are consistent.

In an exemplary implementation, the display area includes a first display area and a second display area. A plurality of first transfer connection electrodes located in the second display area go through the second display area in the first direction, and at least a part of the first transfer connection electrodes located in the second display area are respectively electrically connected to the plurality of data signal lines. A plurality of first transfer connection electrodes located in the first display area do not go through the first display area of the display substrate in the first direction. At least a part of the third transfer connection electrodes are electrically connected to the plurality of first transfer connection electrodes located in the second display area, respectively.

Arrangement modes of first transfer connection electrodes, third transfer connection electrodes and data signal lines in pixels located in the first display area are consistent with arrangement modes of first transfer connection electrodes, third transfer connection electrodes and data signal lines in the pixels located in the second display area.

In an exemplary implementation, the display substrate further includes a plurality of second initial signal lines extending in the second direction, a plurality of second transfer connection electrodes extending in the first direction, and a plurality of fourth transfer connection electrodes extending in the second direction, the second initial signal lines are provided in a same layer as the plurality of data signal lines, the plurality of second transfer connection electrodes are provided in a same layer as the plurality of first transfer connection electrodes, and the plurality of fourth transfer connection electrodes are provided in a same layer as the plurality of third transfer connection electrodes.

The plurality of second transfer connection electrodes located in the second display area go through the second display area of the display substrate in the first direction and are electrically connected to the plurality of second initial signal lines, respectively, and a plurality of second transfer connection electrodes located in the first display area do not go through the first display area of the display substrate in the first direction. At least a part of the fourth transfer connection electrodes are electrically connected to the plurality of second transfer connection electrodes located in the second display area, respectively.

In an exemplary implementation, one pixel includes three sub-pixels. Three columns of sub-pixels and three data signal lines are provided in space of a same column of pixels, and the three columns of sub-pixels are respectively connected to the three data signal lines. Two adjacent columns of pixels share one second initial signal line, and the second initial signal line is located between the two adjacent columns of pixels. Twenty third transfer connection electrodes and one fourth transfer connection electrode are arranged in space of two columns of pixels which share a second initial signal line, ten first transfer connection electrodes are provided in space of each column of pixels, and one second transfer connection electrode is located between the two columns of pixels.

Six first transfer connection electrodes and one second transfer connection electrode are provided in space of a same row of pixels.

In an exemplary implementation, one pixel includes three sub-pixels. Three columns of sub-pixels, three data signal lines, and nine third transfer connection electrodes are provided in space of a same column of pixels, and the three columns of sub-pixels are respectively connected to the three data signal lines. Six first transfer connection electrodes are provided in space of a same row of pixels.

In an exemplary implementation, one pixel includes three sub-pixels. Three columns of sub-pixels, three data signal lines, and three third transfer connection electrodes are provided in space of a same column of pixels, and the three columns of sub-pixels are respectively connected to the three data signal lines. Two first transfer connection electrodes are provided in space of a same row of pixels.

In an exemplary implementation, one sub-pixel includes a first transistor to a fifth transistor and a storage capacitor. The second transistor, the first transistor, the third transistor, the fourth transistor, and the fifth transistor are arranged in the second direction on a plane parallel to the display substrate. An orthographic projection of the storage capacitor on a base substrate is overlapped with an orthographic projection of the third transistor on the base substrate.

In a same pixel, two adjacent sub-pixels are symmetrically provided with respect to a first center line, and the first center line is a center line of the two adjacent sub-pixels extending in a second direction.

In an exemplary implementation, a plurality of sub-pixel groups are included in the same column of sub-pixels, each sub-pixel group includes two adjacent sub-pixels, and two sub-pixels in a same sub-pixel group share a fifth transistor.

In an exemplary implementation, at least one sub-pixel includes a pixel drive circuit, and the pixel drive circuit includes a plurality of oxide transistors and a storage capacitor. In a plane perpendicular to the display substrate, the display substrate includes a base substrate, and a semiconductor layer, a first conductive layer, a second conductive layer, a third conductive layer, a fourth conductive layer and a fifth conductive layer which are stacked sequentially on the base substrate.

The semiconductor layer includes active layers of the plurality of oxide transistors.

The first conductive layer includes control electrodes of the plurality of oxide transistors and a first plate of the storage capacitor.

The second conductive layer includes a second plate of the storage capacitor.

The third conductive layer includes the plurality of data signal lines, and first electrodes and second electrodes of the plurality of oxide transistors.

The fourth conductive layer includes the plurality of first transfer connection electrodes. The fifth conductive layer includes the plurality of third transfer connection electrodes.

In an exemplary implementation, the third conductive layer further includes a plurality of second initial signal lines extending in the second direction. Two adjacent columns of pixels share one of the second initial signal lines, and a plurality of data signal lines in the two columns of pixels which share one second initial signal line are symmetrical with respect to the second initial signal line.

The fourth conductive layer further includes a plurality of second transfer connection electrodes extending in the first direction, and a plurality of second transfer connection electrodes located in the second display area are electrically connected to the plurality of second initial signal lines respectively.

The fifth conductive layer further includes a plurality of fourth transfer connection electrodes extending in the second direction. The plurality of fourth transfer connection electrodes are electrically connected to a plurality of second transfer connection electrodes located in the second display area respectively.

In an exemplary implementation, the first conductive layer further includes a plurality of first power supply connection lines extending in the first direction. A plurality of sub-pixel groups are included in a same column of sub-pixels. Each sub-pixel group includes two adjacent sub-pixels. In a same sub-pixel group, two sub-pixels share one first power supply connection line, and the two sub-pixels in the same sub-pixel group are symmetrical with respect to the first power supply connection line.

The third conductive layer further includes a first power supply line extending in the second direction. The first power supply line is electrically connected to the first power supply connection line through a via.

In an exemplary implementation, the display substrate is a heart-shaped. The bonding area is located on one side of the display area, and the first display area, the second display area, and the bonding area are sequentially arranged in the second direction.

In an exemplary implementation, the at least part of the first transfer connection electrodes are respectively electrically connected to the plurality of data signal lines through a plurality of first transfer vias. The at least part of the third transfer connection electrodes are respectively electrically connected to the at least part of the first transfer connection electrodes through a plurality of third transfer vias. A first included angle is formed between an arrangement direction of the plurality of first transfer vias between a center line of the display substrate extending in the second direction, and a second included angle is formed between an arrangement direction of the plurality of third transfer vias and the center line of the display substrate extending in the second direction.

In an exemplary implementation, the first included angle ranges from 30 degrees to 60 degrees, and the second included angle ranges from 15 degrees to 45 degrees.

In an exemplary implementation, the arrangement direction of the plurality of first transfer vias is provided symmetrically with respect to the center line of the display substrate extending in the second direction, and the arrangement direction of the plurality of third transfer vias is provided symmetrically with respect to the center line of the display substrate extending in the second direction.

In an exemplary implementation, in the display area located on one side of the center line of the display substrate extending in the second direction, a plurality of first transfer vias are arranged in at least two directions, and the at least two arrangement directions are parallel to each other. Connection lines of a plurality of first transfer vias located in the at least two arrangement directions are arranged in the second direction. A plurality of third transfer vias are arranged in at least two directions, and the at least two arrangement directions are parallel to each other. Connection lines of a plurality of third transfer vias located in the at least two arrangement directions are arranged in the second direction.

In an exemplary implementation, the fourth conductive layer further includes anode connection electrodes respectively electrically connected to a plurality of sub-pixels, and orthographic projections of the first transfer connection electrodes and the third transfer connection electrodes on the base substrate are not overlapped with orthographic projections of the plurality of anode connection electrodes on the base substrate.

In an exemplary implementation, the display substrate further includes an anode conductive layer. The anode conductive layer includes a plurality of anodes, and the plurality of anodes are respectively connected to the plurality of anode connection electrodes. There is a first overlapping region between orthographic projections of a plurality of anodes in the same pixel on the base substrate and orthographic projections of the plurality of first transfer connection electrodes and the plurality of third transfer connection electrodes on the base substrate. The plurality of pixels correspond to a plurality of first overlapping regions, and areas of the plurality of first overlapping regions are consistent.

In an exemplary implementation, a size of the bonding region in the first direction is smaller than a size of the display area in the first direction. The plurality of third transfer connection electrodes include two parts, a part of third transfer connection electrodes extend to the bonding region and another part of third transfer connection electrodes do not extend to the bonding region, wherein a plurality of third transfer connection electrodes extending to the bonding region are electrically connected to a plurality of first transfer connection electrodes located in the second display area, respectively.

An embodiment of the present disclosure further provides a display apparatus which includes the display substrate described in any of the aforementioned embodiments.

Other aspects of the present disclosure may be comprehended after the drawings and the detailed descriptions are read and understood.

### BRIEF DESCRIPTION OF DRAWINGS

Accompanying drawings are used to provide an understanding of technical solutions of embodiments of the present disclosure, form a part of the specification, and are used to explain the technical solutions of the present disclosure together with the embodiments of the present disclosure but are not intended to form limitations on the technical solutions of the present disclosure.

FIG. 1 shows a schematic diagram of a structure of a display apparatus.

FIG. 2 shows a schematic diagram of a planar structure of a display substrate.

FIG. 3 shows a schematic diagram of a cross-sectional structure of a display substrate.

FIG. 4 shows a schematic diagram of an equivalent circuit of a pixel drive circuit.

FIG. 5 shows a schematic diagram of a planar structure of a display substrate according to an embodiment of the present disclosure.

FIG. 6a shows a schematic diagram of a planar structure of a display substrate according to an exemplary embodiment of the present disclosure.

FIG. 6b shows a schematic diagram of a planar structure of a display substrate according to an exemplary embodiment of the present disclosure.

FIG. 6c shows a schematic diagram of a planar structure of a display substrate according to an exemplary embodiment of the present disclosure.

FIG. 7 shows a schematic diagram of a display substrate according to an exemplary embodiment of the present disclosure after a pattern of a semiconductor layer is formed.

FIG. 8a shows a schematic diagram of a display substrate according to an exemplary embodiment of the present disclosure after a pattern of a first conductive layer is formed.

FIG. 8b shows a schematic diagram of a first conductive layer in a display substrate according to an exemplary embodiment of the present disclosure.

FIG. 9a shows a schematic diagram of a display substrate according to an exemplary embodiment of the present disclosure after a pattern of a second conductive layer is formed.

FIG. 9b shows a schematic diagram of a second conductive layer in a display substrate according to an exemplary embodiment of the present disclosure.

FIG. 10 shows a schematic diagram of a display substrate according to an exemplary embodiment of the present disclosure after a pattern of a fourth insulation layer is formed.

FIG. 11a shows a schematic diagram of a display substrate according to an exemplary embodiment of the present disclosure after a pattern of a third conductive layer is formed.

FIG. 11b shows a schematic diagram of a third conductive layer in a display substrate according to an exemplary embodiment of the present disclosure.

FIG. 12a shows a schematic diagram of a display substrate according to an exemplary embodiment of the present disclosure after patterns of a fifth insulation layer and a first planarization layer are formed.

FIG. 12b shows a schematic diagram of a display substrate according to an exemplary embodiment of the present disclosure after patterns of a fifth insulation layer and a first planarization layer are formed.

FIG. 13a shows a schematic diagram of a display substrate according to an exemplary embodiment of the present disclosure after a pattern of a fourth conductive layer is formed.

FIG. 13b shows a schematic diagram of a fourth conductive layer in a display substrate according to an exemplary embodiment of the present disclosure.

FIG. 13c shows a schematic diagram of a display substrate according to an exemplary embodiment of the present disclosure after a pattern of a fourth conductive layer is formed.

FIG. 14 shows a schematic diagram of a display substrate according to an exemplary embodiment of the present disclosure after patterns of a sixth insulation layer and a second planarization layer are formed.

FIG. 15a shows a schematic diagram of a display substrate according to an exemplary embodiment of the present disclosure after a pattern of a fifth conductive layer is formed.

FIG. 15b shows a schematic diagram of a fifth conductive layer in a display substrate according to an exemplary embodiment of the present disclosure.

FIG. 15c shows a schematic diagram of a display substrate according to an exemplary embodiment of the present disclosure after a pattern of a fifth conductive layer is formed.

FIG. 15d shows a schematic diagram of a display substrate according to an exemplary embodiment of the present disclosure after a pattern of a fifth conductive layer is formed.

FIG. 16 shows a schematic diagram of a display substrate according to an exemplary embodiment of the present disclosure after a pattern of a third planarization layer is formed.

FIG. 17a shows a schematic diagram of a display substrate according to an exemplary embodiment of the present disclosure after a pattern of an anode conductive layer is formed.

FIG. 17b shows a schematic diagram of an anode conductive layer in a display substrate according to an exemplary embodiment of the present disclosure.

FIG. 18 shows a schematic diagram of a display substrate according to an exemplary embodiment of the present disclosure after a pattern of a pixel definition layer is formed.

FIG. 19 shows a schematic diagram of a planar structure of a display substrate according to an exemplary embodiment of the present disclosure.

FIG. 20 shows a schematic diagram of a display substrate according to an exemplary embodiment of the present disclosure after a pattern of a pixel definition layer is formed.

FIG. 21 shows a schematic diagram of a planar structure of a display substrate according to an exemplary embodiment of the present disclosure.

FIG. 22 shows a schematic diagram of a bezel region of a display substrate according to an exemplary embodiment of the present disclosure.

### DETAILED DESCRIPTION

The embodiments of the present disclosure will be described in detail below with reference to the accompanying drawings. Implementations may be implemented in a plurality of different forms. Those of ordinary skills in the art can easily understand such a fact that implementations and contents may be transformed into various forms without departing from the purpose and scope of embodiments of the present disclosure. Therefore, the embodiments of the present disclosure should not be explained as being limited to the contents recorded in the following implementations only. The embodiments in the present disclosure and features in the embodiments may be combined with each other randomly if there is no conflict. In order to keep following description of the embodiments of the present disclosure clear and concise, detailed description of part of known functions and known components are omitted in the embodiments of the present disclosure. The drawings in the embodiments of the present disclosure relate only to the structures involved in the embodiments of the present disclosure, and other structures may be described with reference to conventional designs.

Scales of the drawings in the present disclosure may be used as a reference in actual processes, but are not limited thereto. For example, a thickness and a pitch of each film layer, and a width and a pitch of each signal line may be adjusted according to an actual situation. The drawings described in the embodiments of the present disclosure are only schematic diagrams of structures, and one implementation of the embodiments of the present disclosure is not limited to shapes or numerical values or the like shown in the drawings.

Ordinal numerals “first”, “second”, “third”, etc., in the specification are set not to form limits in numbers but only to avoid confusion between constituent elements.

In the specification, for convenience, expressions “central”, “above”, “below”, “front”, “back”, “vertical”, “horizontal”, “top”, “bottom”, “inside”, “outside”, etc., indicating directional or positional relationships are used to illustrate positional relationships between the constituent elements with reference to the accompanying drawings, not to indicate or imply that involved devices or elements are required to have specific orientations and be structured and operated with the specific orientations but only to easily and simply describe the present specification, and thus should not be understood as limitations on the present disclosure. The positional relationships between the constituent elements may be changed as appropriate according to a direction which is used for describing each constituent element. Therefore, appropriate replacements based on situations are allowed, which is not limited to the expressions in the specification.

In the specification, unless otherwise specified and defined, terms “mounting”, “mutual connection”, and “connection” should be understood in a broad sense. For example, a connection may be a fixed connection, or a detachable connection, or an integral connection; it may be a mechanical connection or an electrical connection; it may be a direct connection, or an indirect connection through middleware, or internal communication inside two elements. Those of ordinary skills in the art may understand specific meanings of the above terms in the present disclosure according to specific situations.

In the specification, a transistor refers to an element that at least includes three terminals, i.e., a gate electrode, a drain electrode, and a source electrode. The transistor has a channel region between the drain electrode (drain electrode terminal, drain region, or drain) and the source electrode (source electrode terminal, source region, or source), and a current can flow through the drain electrode, the channel region, and the source electrode. It is to be noted that in the specification, the channel region refers to a region through which a current mainly flows.

In the specification, a first electrode may be a drain electrode, and a second electrode may be a source electrode. Or, the first electrode may be a source electrode, and the second electrode may be a drain electrode. In a case that transistors with opposite polarities are used, or in a case that a direction of a current changes during operation of a circuit, or the like, functions of the “source electrode” and the “drain electrode” are sometimes interchangeable. Therefore, the “source electrode” and the “drain electrode”, as well as a “source terminal” and a “drain terminal”, are interchangeable in the specification. In an embodiment of the present disclosure, the gate electrode may be referred to as a control electrode.

In the specification, an “electrical connection” includes a case that constituent elements are connected together through an element with a certain electrical action. An “element with a certain electrical action” is not particularly limited as long as electrical signals between the connected constituent elements can be sent and received. Examples of the “element with a certain electrical action” not only include an electrode and a wiring, but also include a switching element such as a transistor, a resistor, an inductor, a capacitor, another element with various functions, etc.

In the specification, “parallel” refers to a state in which an angle formed by two straight lines is above −10° and below 10°, and thus may include a state in which the angle is above −5° and below 5°. In addition, “perpendicular” refers to a state in which an angle formed by two straight lines is above 80° and below 100°, and thus may include a state in which the angle is above 85° and below 95°.

In the specification, a “film” and a “layer” are interchangeable. For example, a “conductive layer” may be replaced with a “conductive film” sometimes. Similarly, an “insulation film” may be replaced with an “insulation layer” sometimes.

A triangle, rectangle, trapezoid, pentagon, or hexagon, etc. in the specification is not strictly defined, and it may be an approximate triangle, rectangle, trapezoid, pentagon, or hexagon, etc. There may be some small deformations caused by tolerance, and there may be a chamfer, an arc edge, deformation, etc.

In an embodiment of the present disclosure, “about” refers to a value that is not strictly limited, a value within a range of process and measurement error is allowed.

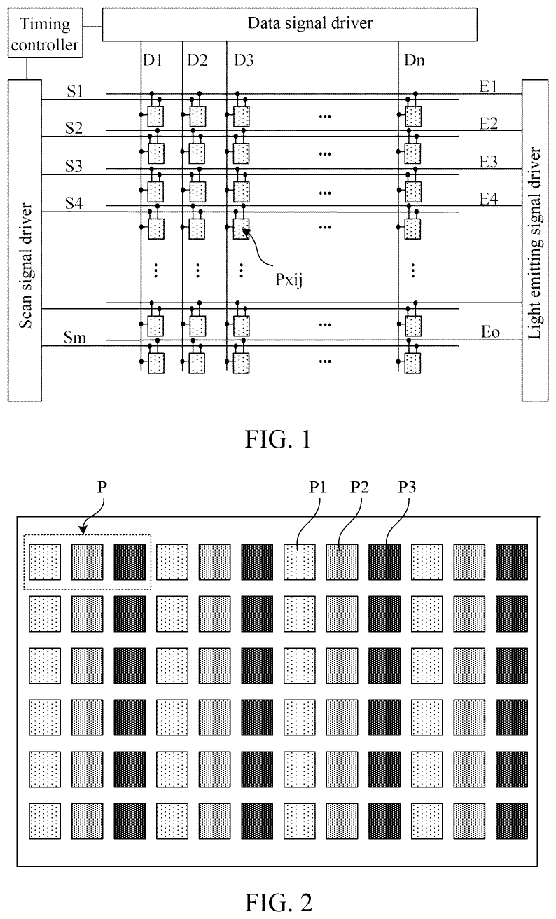

FIG. 1 shows a schematic diagram of a structure of a display apparatus, the display substrate may include a timing controller, a data signal driver, a scan signal driver, a light emitting signal driver, and a pixel array. The timing controller is connected with the data signal driver, the scan signal driver, and the light emitting signal driver respectively, the data signal driver is connected with a plurality of data signal lines (D1 to Dn) respectively, the scan signal driver is connected with a plurality of scan signal lines (S1 to Sm) respectively, and the light emitting signal driver is connected with a plurality of light emitting signal lines (E1 to Eo) respectively. The pixel array may include a plurality of sub-pixels Pxij, wherein i and j may be natural numbers. At least one sub-pixel Pxij may include a circuit unit and a light emitting device connected to the circuit unit, and the circuit unit may include at least one scan signal line, at least one data signal line, at least one light emitting signal line, and a pixel drive circuit. In an exemplary implementation, the timing controller may provide a gray scale value and a control signal suitable for a specification of the data signal driver to the data signal driver, may provide a clock signal, and a scan start signal, etc., suitable for a specification of the scan signal driver to the scan signal driver, and may provide a clock signal, and an emission stop signal, etc., suitable for a specification of the light emitting signal driver to the light emitting signal driver. The data signal driver may generate data voltages to be provided to data signal lines D1, D2, D3, . . . , and Dn using the gray scale value and the control signal received from the timing controller. For example, the data signal driver may sample the gray scale value using the clock signal and apply a data voltage corresponding to the gray scale value to the data signal lines D1 to Dn by taking a pixel row as a unit, wherein n may be a natural number. The scan signal driver may generate scan signals to be provided to scan signal lines S1, S2, S3, . . . , and Sm by receiving the clock signal, the scan start signal, and the like from the timing controller. For example, the scan signal driver may sequentially provide scan signals with on-level pulses to the scan signal lines S1 to Sm. For example, the scan signal driver may be constructed in a form of a shift register, and generate the scan signals by sequentially transmitting the scan start signal provided in a form of on-level pulses to a next-stage circuit under control of the clock signal, wherein m may be a natural number. The light emitting signal driver may generate an emission signal to be provided to emitting signal lines E1, E2, E3, . . . , and Eo by receiving the clock signal, the transmission stop signal, and the like from the timing controller. For example, the light emitting signal driver may sequentially provide an emission signal with an off-level pulse to the light emitting signal lines E1 to Eo. For example, the light emitting driver may be constructed in a form of a shift register and generate an emission signal in a manner of sequentially transmitting an emission stop signal provided in a form of an off-level pulse to a next-stage circuit under control of the clock signal, wherein o may be a natural number.

FIG. 2 is a schematic diagram of a planar structure of a display substrate. As shown in FIG. 2, the display substrate may include a plurality of pixel units P arranged in a matrix, at least one of the plurality of pixel units P includes a first sub-pixel P1 emitting light of a first color, a second sub-pixel P2 emitting light of a second color, and a third sub-pixel P3 emitting light of a third color. The first sub-pixel P1, the second sub-pixel P2, and the third sub-pixel P3 each include a pixel drive circuit and a light emitting device. Pixel drive circuits in the first sub-pixel P1, the second sub-pixel P2, and the third sub-pixel P3 are connected with a scan signal line, a data signal line, and a light emitting signal line respectively. A pixel drive circuit is configured to receive a data voltage transmitted by the data signal line under control of the scan signal line and the light emitting signal line, and output a corresponding current to the light emitting device. Light emitting devices in the first sub-pixel P1, the second sub-pixel P2, and the third sub-pixel P3 are respectively connected with the pixel drive circuit of the sub-pixel in which the light emitting device is located, and the light emitting device is configured to emit light with a corresponding brightness in response to a current outputted by the pixel drive circuit of the sub-pixel in which the light emitting device is located.

In an exemplary implementation, a pixel unit P may include a red (R) sub-pixel, a green (G) sub-pixel, and a blue (B) sub-pixel. In an exemplary implementation, a sub-pixel in the pixel unit may be in a shape of a rectangle, a rhombus, a pentagon, or a hexagon. The three sub-pixels may be arranged side by side horizontally, side by side vertically, or in a delta-shaped arrangement, which is not limited in the present disclosure.

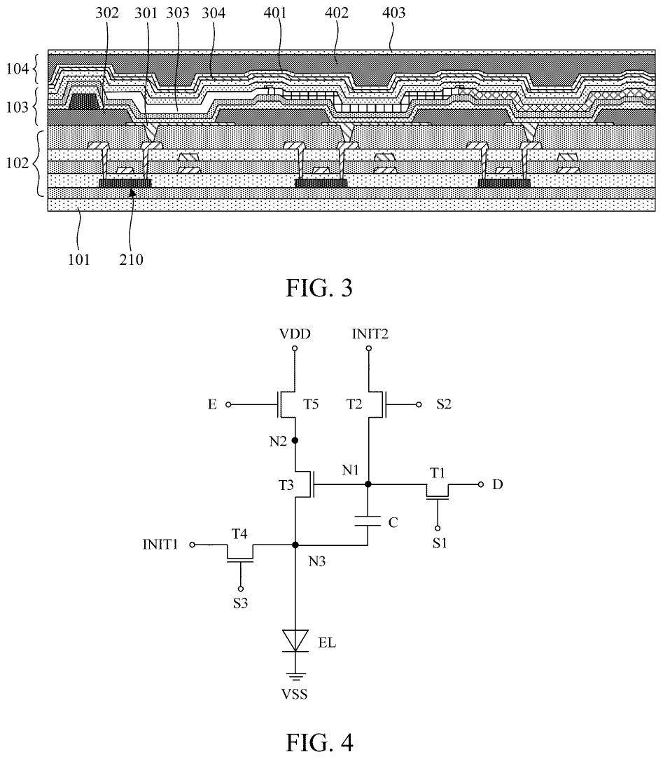

FIG. 3 is a schematic diagram of a cross-sectional structure of a display substrate, which illustrates a structure of three sub-pixels of an OLED display substrate. As shown in FIG. 3, on a plane perpendicular to the display substrate, the display substrate may include a drive circuit layer 102 disposed on a base substrate 101, a light emitting structure layer 103 disposed on a side of the drive circuit layer 102 away from the base substrate 101, and an encapsulation layer 104 disposed on a side of the light emitting structure layer 103 away from the base substrate 101. In some possible implementations, the display substrate may include another film layer, such as a post spacer, which is not limited in the present disclosure.

In an exemplary implementation, the base substrate 101 may be a flexible base substrate, or may be a rigid base substrate. The drive circuit layer 102 of each sub-pixel may include a plurality of transistors and a storage capacitor constituting a pixel drive circuit. The light emitting structure layer 103 may include an anode 301, a pixel definition layer 302, an organic light emitting layer 303 and a cathode 304. The anode 301 is connected to a drain electrode of a drive transistor 210 through a via, the organic light emitting layer 303 is connected to the anode 301, and the cathode 304 is connected to the organic light emitting layer 303. The organic light emitting layer 303 emits light of a corresponding color under driving of the anode 301 and the cathode 304. The encapsulation layer 104 may include a first encapsulation layer 401, a second encapsulation layer 402, and a third encapsulation layer 403 that are stacked. The first encapsulation layer 401 and the third encapsulation layer 403 may be made of an inorganic material, the second encapsulation layer 402 may be made of an organic material, and the second encapsulation layer 402 is disposed between the first encapsulation layer 401 and the third encapsulation layer 403 so as to prevent external moisture from entering the light emitting structure layer 103.

In an exemplary implementation, the organic light emitting layer 303 may include a Hole Injection Layer (HIL), a Hole Transport Layer (HTL), an Electron Block Layer (EBL), an Emitting Layer (EML), a Hole Block Layer (HBL), an Electron Transport Layer (ETL), and an Electron Injection Layer (EIL) which are stacked. In an exemplary implementation, hole injection layers of all sub-pixels may be connected together to be a common layer, electron injection layers of all the sub-pixels may be connected together to be a common layer, hole transport layers of all the sub-pixels may be connected together to be a common layer, electron transport layers of all the sub-pixels may be connected together to be a common layer, hole block layers of all the sub-pixels may be connected together to be a common layer, emitting layers of adjacent sub-pixels may be overlapped slightly or may be isolated, and electron block layers of adjacent sub-pixels may be overlapped slightly or may be isolated.

In an exemplary implementation, the pixel drive circuit may be in a structure of 3T1C, 4T1C, 5T1C, 5T2C, 6T1C, or 7T1C. FIG. 4 is a schematic diagram of an equivalent circuit of a pixel drive circuit. As shown in FIG. 4, the pixel drive circuit may include five transistors (a first transistor T1 to a fifth transistor T5) and one storage capacitor C, and the pixel drive circuit may be connected with seven signal lines (a data signal line D, a first scan signal line S1, a second scan signal line S2, a light emitting signal line E, a first initial signal line INIT1, a second initial signal line INIT2, a first power supply line VDD, and a second power supply line VSS).

In an exemplary implementation, the pixel drive circuit may include a first node N1, a second node N2, and a third node N3. The first node N1 is respectively connected with a second electrode of the first transistor T1, a second electrode of the second transistor T2, a control electrode of the third transistor T3, and a first plate of the storage capacitor C. The second node N2 is respectively connected with a first electrode of the third transistor T3 and a second electrode of the fifth transistor T5. The third node N3 is respectively connected with a second electrode of the third transistor T3, a second electrode of the fourth transistor T4, and a second plate of the storage capacitor C.

In an exemplary embodiment, the first plate of the storage capacitor C is connected with the first node N1, and the second plate of the storage capacitor C is connected with the third node N3, i.e., the first plate of the storage capacitor C is connected with the control electrode of the third transistor T3.

A control electrode of the first transistor T1 is connected with the first scan signal line S1, a first electrode of the first transistor T1 is connected with the data signal line D, and a second electrode of the first transistor is connected with the first node N1. When a scan signal with an on-level is applied to the first scan signal line S1, the first transistor T1 enables a data voltage of the data signal line D to be input to the pixel drive circuit.

A control electrode of the second transistor T2 is connected with the second scan signal line S2, a first electrode of the second transistor T2 is connected with the second initial signal line INIT2, and a second electrode of the second transistor T2 is connected with the first node N1. When a scan signal with an on-level is applied to the second scan signal line S2, the second transistor T2 transmits an initial voltage of the second initial signal line INIT2 to the control electrode of the third transistor T3 so as to initialize a charge amount of the control electrode of the third transistor T3.

The control electrode of the third transistor T3 is connected with the first node N1, i.e., the control electrode of the third transistor T3 is connected with the first plate of the storage capacitor C, the first electrode of the third transistor T3 is connected with the second node N2, and the second electrode of the third transistor T3 is connected with the third node N3. The third transistor T3 may be referred to as a drive transistor, and the third transistor T3 determines a magnitude of a drive current flowing between the first power supply line VDD and the second power supply line VSS according to a potential difference between the control electrode and the first electrode of the third transistor T3. A control electrode of the fourth transistor T4 is connected with the third scan signal line S3, a first electrode of the fourth transistor T4 is connected with a first initial signal line INIT1, and a second electrode of the fourth transistor T4 is connected with the third node N3. When a scan signal with an on-level is applied to the third scan signal line S3, the fourth transistor T4 transmits an initial voltage of the first initial signal line INIT1 to a first electrode of the light emitting device so as to initialize a charge amount accumulated in the first electrode of the light emitting device or release a charge amount accumulated in the first electrode of the light emitting device.

A control electrode of the fifth transistor T5 is connected with the light emitting signal line E, a first electrode of the fifth transistor T5 is connected with the first power supply line VDD, and a second electrode of the fifth transistor T5 is connected with the second node N2. The fifth transistor T5 may be referred to as a light emitting transistor. When a light emitting signal with an on-level is applied to the light emitting signal line E, the fifth transistor T5 enables the light emitting device to emit light by forming a drive current path between the first power supply line VDD and the second power supply line VSS.

In an exemplary implementation, a second electrode of the light emitting device is connected to the second power supply line VSS, a signal of the second power supply line VSS is a low-level signal, and a signal of the first power supply line VDD is a high-level signal continuously provided.

In an exemplary implementation, the first transistor T1 to the fifth transistor T5 may be P-type transistors, or may be N-type transistors. Use of a same type of transistors in a pixel drive circuit may simplify a process flow, reduce a process difficulty of a display panel, and improve a product yield. In some possible implementations, the first transistor T1 to the fifth transistor T5 may include P type transistors and N type transistors.

In an exemplary implementation, the first scan signal line S1, the second scan signal line S2, the light emitting signal line E and the first initial signal line INIT1 may extend along a horizontal direction, and the second power supply line VSS, the first power supply line VDD, the second initial signal line INIT2, and the data signal line D may extend along a vertical direction.

In an exemplary implementation, the light emitting device may be an Organic Light Emitting Diode (OLED) including a first electrode (anode), an organic light emitting layer, and a second electrode (cathode) that are stacked.

Due to varied shapes of customized products of display substrates, and in order to meet the needs of high-end customers, a bezel needs to be as small as possible, resulting in data signal lines or other longitudinal signal lines of some pixels having to cross a display area (Fanout in AA, abbreviated as FIAA). This technology in which data signal traces and other longitudinal signal traces pass through the display area is called FIA technology. For a top-emission device, many FIA traces need to pass under a anode of the device. Due to limited planarization of the planarization layer, such traces will lead to a certain segment difference in an anode layer, thereby causing non-uniform light emission.

An embodiment of the present disclosure provides a display substrate, which may include a display area and a bonding area connected to the display area. The display area includes a plurality of data signal lines extending in a second direction, a plurality of first transfer connection electrodes extending in a first direction, a plurality of third transfer connection electrodes extending in the second direction, and a plurality of sub-pixels arranged in an array. The plurality of data signal lines are respectively connected to a plurality of columns of sub-pixels, and the data signal lines, the first transfer connection electrodes, and the third transfer connection electrodes are respectively provided in three conductive layers.

At least a part of the first transfer connection electrodes are respectively electrically connected to the plurality of data signal lines, and are respectively electrically connected to at least a part of the third transfer connection electrodes. One ends of the third transfer connection electrodes connected to the at least part of the first transfer connection electrodes are electrically connected to the bonding area. In the display area, lengths of the plurality of data signal lines along the second direction are not identical.

The plurality of sub-pixels form a plurality of pixels arranged in an array. A pixel includes at least three adjacent sub-pixels, and the arrangement modes of a plurality of first transfer connection electrodes and a plurality of third transfer connection electrodes located in two pixels are consistent.

In the display substrate according to the embodiment of the present disclosure, the display area includes a plurality of data signal lines, a plurality of first transfer connection electrodes, a plurality of third transfer connection electrodes, and a plurality of sub-pixels arranged in an array. At least a part of the first transfer connection electrodes are respectively electrically connected to a plurality of data signal lines, and are respectively electrically connected to at least a part of the third transfer connection electrodes. One ends of the third transfer connection electrodes connected to the at least part of the first transfer connection electrodes are electrically connected to the bonding area. In the display area, the lengths of the plurality of data signal lines along the second direction are not identical. The plurality of sub-pixels form a plurality of pixels arranged in an array, a pixel includes at least three adjacent sub-pixels, and arrangement modes of a plurality of first transfer connection electrodes and a plurality of third transfer connection electrodes located in two pixels are consistent. In the display substrate according to the embodiment of the present disclosure, arrangement modes of the plurality of first transfer connection electrodes and the plurality of third transfer connection electrodes located in two pixels are consistent, so that segment differences of anodes in the plurality of pixels are consistent, which can effectively avoid occurrences of non-uniform light emission. In the display substrate according to the embodiment of the present disclosure, the lengths of the plurality of data signal lines along the second direction in the display area are not identical, so that the display substrate can be suitable for use as a special-shaped display substrate, and that the non-uniform light emission of a special-shaped display substrate due to inconsistent segment differences of anodes can be avoided.

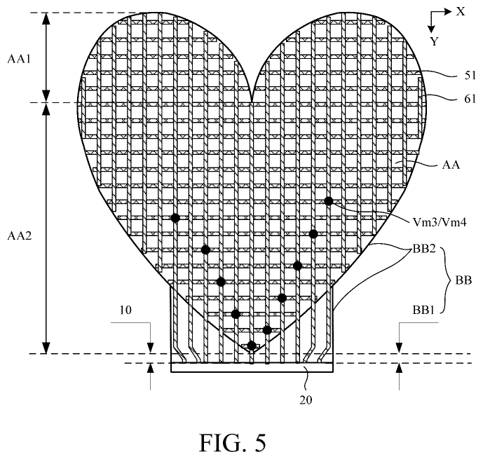

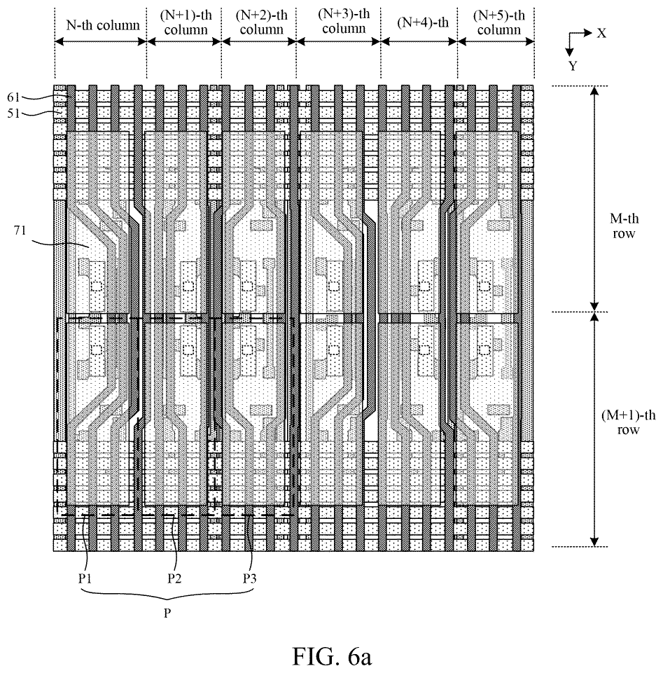

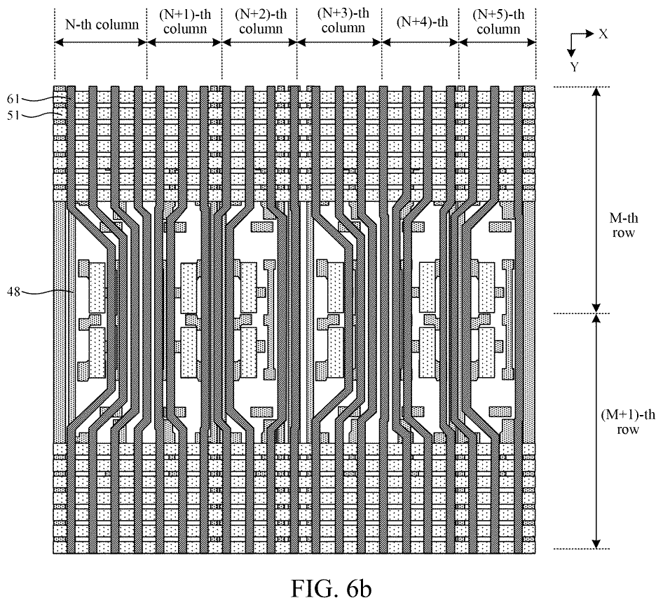

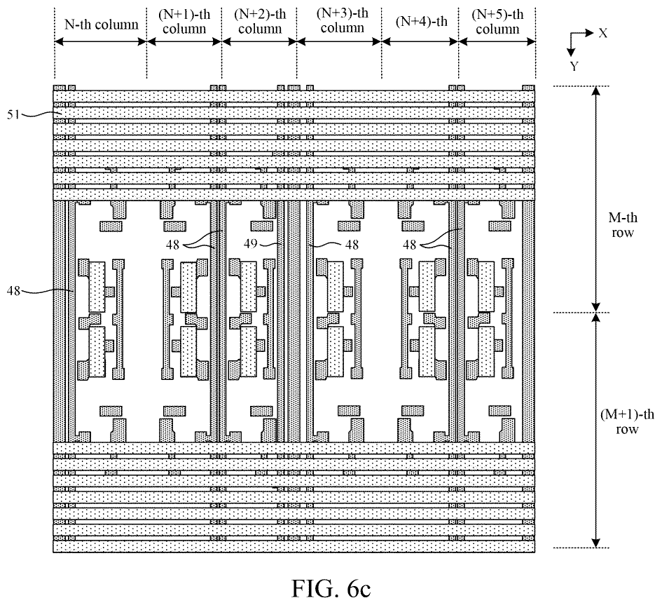

In an exemplary implementation, as shown in FIGS. 5 to 6c, a display substrate may include a display area AA and a bonding area 10 connected to the display area AA. The display area AA includes a plurality of data signal lines 48 extending in a second direction Y, a plurality of first transfer connection electrodes 51 extending in a first direction X, a plurality of third transfer connection electrodes 61 extending in the second direction Y, and a plurality of sub-pixels arranged in an array. The plurality of data signal lines 48 are respectively connected to a plurality of columns of sub-pixels. The data signal lines 48, the first transfer connection electrodes 51, and the third transfer connection electrodes 61 are respectively provided in three conductive layers. At least a part of the first transfer connection electrodes 51 are electrically connected to a plurality of data signal lines 48 respectively, and are electrically connected to at least a part of the third transfer connection electrodes 61 respectively. One ends of the third transfer connection electrodes 61 electrically connected to the at least part of the first transfer connection electrodes 51 are electrically connected to the bonding area 10. In the display area AA, lengths of the plurality of data signal lines 48 along the second direction Y are not identical. A plurality of sub-pixels form a plurality of pixels P arranged in an array. A pixel P includes at least three adjacent sub-pixels. Arrangement modes of a plurality of first transfer connection electrodes 51 and a plurality of third transfer connection electrodes 61 located in two pixels P are consistent.

In an exemplary implementation, arrangement modes of a plurality of first transfer connection electrodes 51, a plurality of third transfer connection electrodes 61, and a plurality of data signal lines 48 located in two pixels P are consistent, so as to improve consistency of traces under anodes of a plurality of pixels and avoid non-uniform light emission caused by inconsistent segment differences of anodes among a plurality of pixels. For example, at least a part of the quantity, line width, area, extension direction, and arrangement direction of a plurality of first transfer connection electrodes 51, a plurality of third transfer connection electrodes 61, and a plurality of data signal lines 48 located in two pixels P are consistent.

In an exemplary implementation, as shown in FIG. 5, the display area AA may include a first display area AA1 and a second display area AA2. A plurality of first transfer connection electrodes 51 located in the second display area AA2 go through the second display area AA2 in the first direction X, and at least a part of the first transfer connection electrodes 51 located in the second display area AA2 are electrically connected to a plurality of data signal lines 48 respectively. A plurality of first transfer connection electrodes 51 located in the first display area AA1 do not go through the first display area AA1 in the first direction X. At least a part of the third transfer connection electrodes 61 are electrically connected to the plurality of first transfer connection electrodes 51 located in the second display area AA2, respectively. Arrangement modes of first transfer connection electrodes 51, third transfer connection electrodes 61, and data signal lines 48 in the pixels located in the first display area AA1 are consistent with arrangement modes of first transfer connection electrodes 51, third transfer connection electrodes 61, and data signal lines 48 in the pixels located the second display area AA2.

In an exemplary implementation, at least a part of the quantity, line width, area, extension direction, and arrangement direction of first transfer connection electrodes 51, third transfer connection electrodes 61, and data signal lines 48 in the pixels located in the first display area AA1 are consistent with those in the second display area AA2, so as to improve consistency of traces under anodes of a plurality of pixels located in the first display area AA1 and the second display area AA2, avoid non-uniform light emission caused by inconsistent segment differences of anodes among the plurality of pixels, and thereby improve the uniformity of light emission in the display area AA. For example, the quantities, line widths, areas, extension directions and arrangement directions of the first transfer connection electrodes 51, the third transfer connection electrodes 61, and the data signal lines 48 in the pixels located in the first display area AA1 and the second display area AA2 are all the same.

In an exemplary implementation, as shown in FIG. 5, a plurality of first transfer connection electrodes 51 located in the second display area AA2 go through the second display area AA2 in the first direction X, that is, the plurality of first transfer connection electrodes 51 located in the second display area AA2 are not disconnected in the first direction X, and are communicated in the second display area AA2. A plurality of first transfer connection electrodes 51 located in the first display area AA1 do not go through the first display area AA1 in the first direction X, that is, the plurality of first transfer connection electrodes 51 located in the first display area AA1 are disconnected in the first direction X, and are not communicated in the first display area AA1.

In the display substrate according to the embodiment of the present disclosure, the arrangement modes of first transfer connection electrodes 51, third transfer connection electrodes 61, and data signal lines 48 in the pixels located in the first display area are consistent with the arrangement modes of first transfer connection electrodes 51, third transfer connection electrodes 61, and data signal lines 48 in the pixels located in the second display area, so that segment differences of anodes in a plurality of pixels are consistent, and occurrences of non-uniform light emission can be effectively avoided. The display substrate according to the embodiment of the present disclosure can be suitable for use as a special-shaped display substrate, and occurrences of non-uniform light emission of the special-shaped display substrate due to inconsistent segment differences of anodes can be avoided.

In an embodiment of the present disclosure, as shown in FIG. 5, a plurality of first transfer connection electrodes 51 located in the first display area AA1 may not participate in signal transmission, but may play a role in improving the consistency of traces under anodes of a plurality of pixels and avoiding non-uniform light emission due to inconsistent segment differences of anodes.

In an exemplary implementation, at least a part of the first transfer connection electrodes 51 located in the second display area AA2 are electrically connected to the plurality of data signal lines 48, respectively, which may include two cases. One case is that a quantity of all the first transfer connection electrodes 51 located in the second display area AA2 is the same as a quantity of data signal lines 48, and all the first transfer connection electrodes 51 located in the second display area AA2 are electrically connected to the plurality of data signal lines 48 respectively. Another case is that the quantity of all the first transfer connection electrodes 51 located in the second display area AA2 is larger than the quantity of data signal lines 48, a part of the first transfer connection electrodes 51 located in the second display area AA2 are electrically connected to the plurality of data signal lines 48 respectively, and another part of the first transfer connection electrodes 51 located in the second display area AA2 may be used as a parallel structure of the first power supply line VDD or the second power supply line VSS to reduce a voltage drop of the first power supply line VDD or the second power supply line VSS.

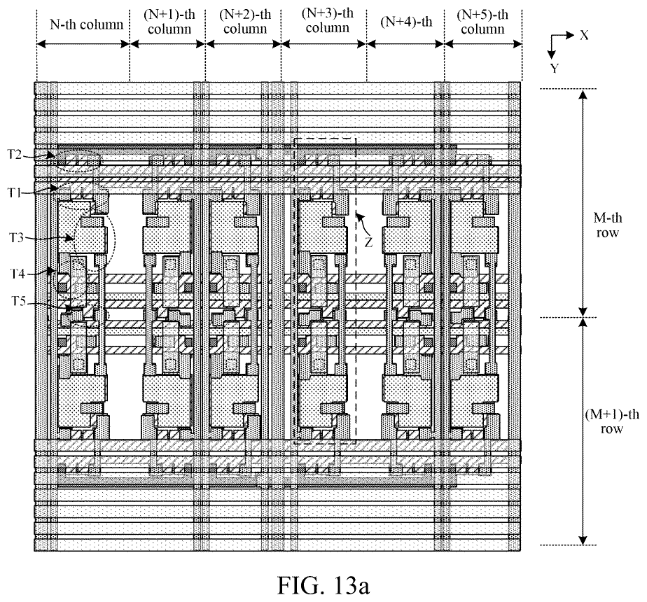

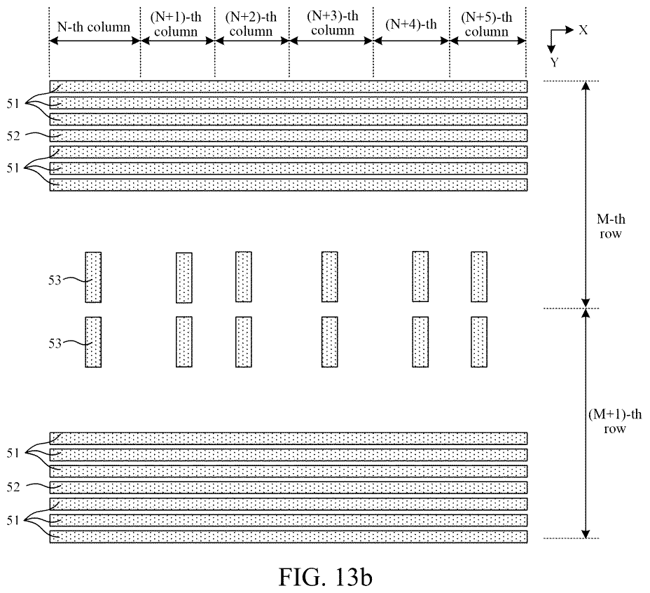

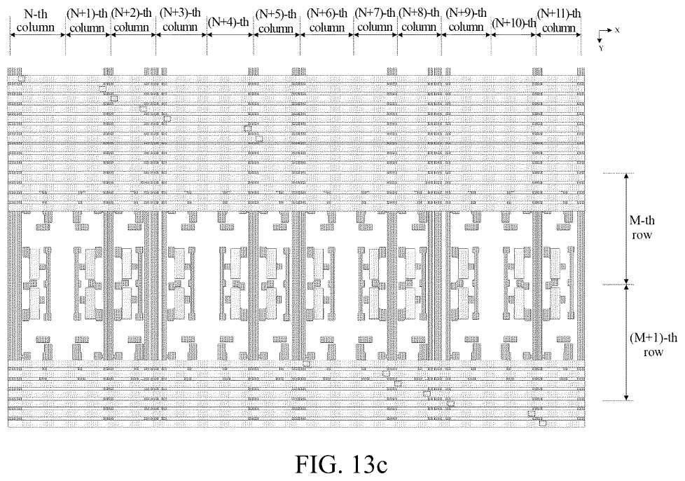

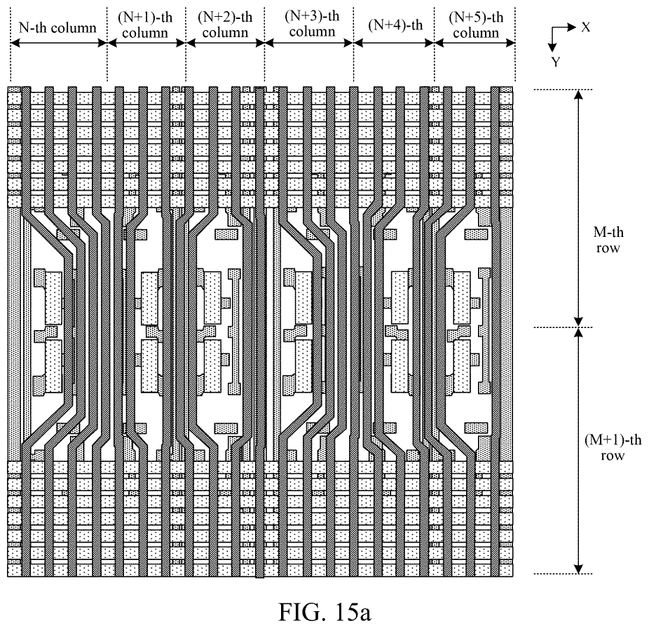

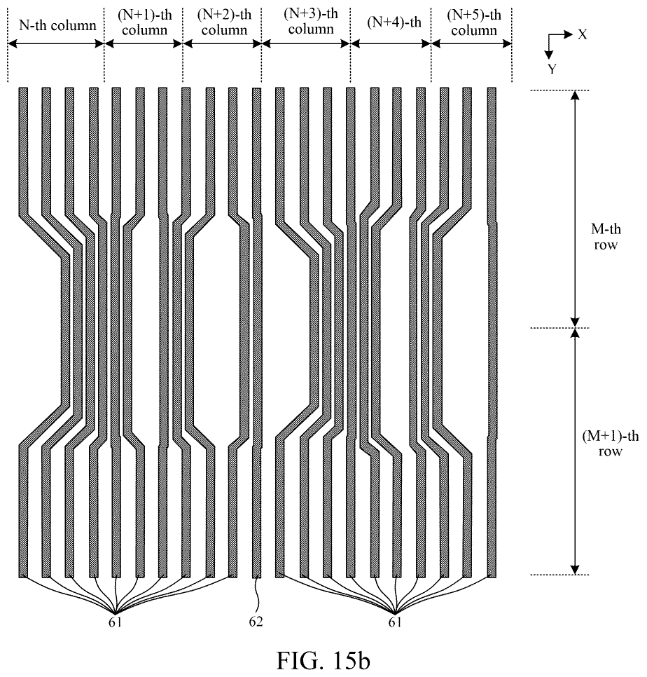

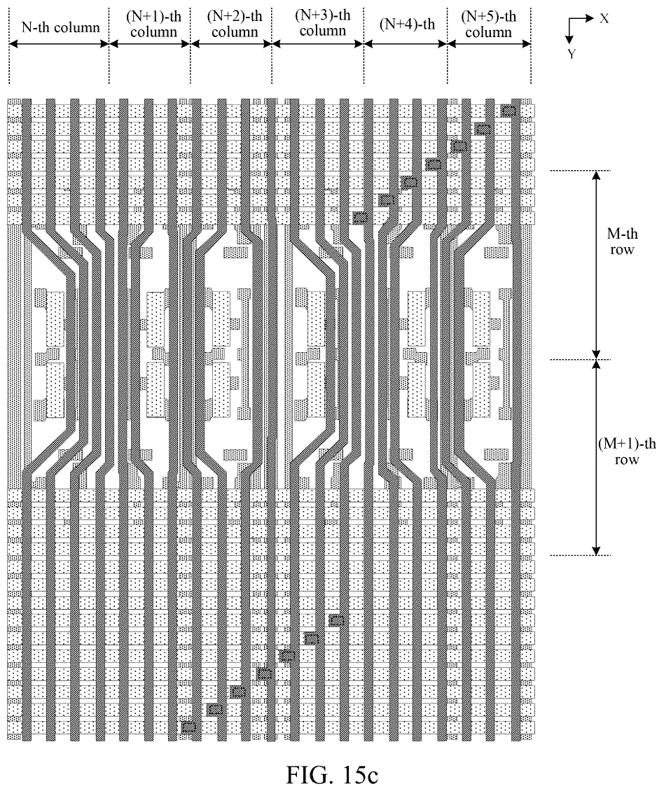

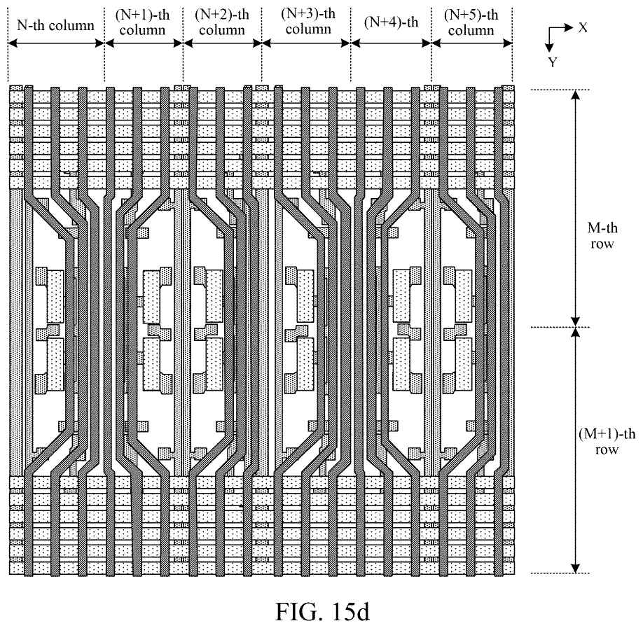

In an exemplary implementation, as shown in FIGS. 13b and 15b, the display substrate may further include a plurality of second initial signal lines 49 extending in the second direction Y, a plurality of second transfer connection electrodes 52 extending in the first direction X, and a plurality of fourth transfer connection electrodes 62 extending in the second direction Y. The second initial signal lines 49 are provided in a same layer as the plurality of data signal lines 48, the plurality of second transfer connection electrodes 52 are provided in a same layer as the plurality of first transfer connection electrodes 51, and the plurality of fourth transfer connection electrodes 62 are provided in a same layer as the plurality of third transfer connection electrodes 61.

A plurality of second transfer connection electrodes 52 located in the second display area AA2 go through the second display area AA2 of the display substrate in the first direction X, and are electrically connected to a plurality of second initial signal lines 49 respectively. A plurality of second transfer connection electrodes 52 located in the first display area AA1 do not go through the first display area AA1 of the display substrate in the first direction X. At least a part of the fourth transfer connection electrodes 62 are electrically connected to a plurality of second transfer connection electrodes 52 located in the second display area AA2, respectively.

In an exemplary implementation, a plurality of second transfer connection electrodes 52 located in the second display area AA2 go through the second display area AA2 of the display substrate in the first direction X, that is, the plurality of second transfer connection electrodes 52 located in the second display area AA2 are not disconnected in the first direction X and are communicated. A plurality of second transfer connection electrodes 52 located in the first display area AA1 do not go through the first display area AA1 of the display substrate in the first direction X, that is, the plurality of second transfer connection electrodes 52 located in the first display area AA1 are disconnected in the first direction X and not communicated.

In an exemplary implementation, in a plane parallel to the display substrate, the plurality of data signal lines 48 and the plurality of second initial signal lines 49 extend in the second direction Y and are arranged in the first direction X. The plurality of first transfer connection electrodes 51 and the plurality of second transfer connection electrodes 52 extend in the first direction X and are arranged in the second direction Y. The plurality of third transfer connection electrodes 61 and the plurality of fourth transfer connection electrodes 62 extend in the second direction Y and are arranged in the first direction X. The first direction X intersects the second direction Y.

In an exemplary implementation, as shown in FIGS. 6a to 6c, a pixel P may include three sub-pixels P1, P2, and P3. Three columns of sub-pixels and three data signal lines 48 may be provided in space of a same column of pixels. The three columns of sub-pixels are respectively connected to the three data signal lines 48, two adjacent columns of pixels share a same second initial signal line 49, and the second initial signal line 49 is located between the two adjacent columns of pixels. 20 third transfer connection electrodes 61 and one fourth transfer connection electrode 62 are provided in space of two columns of pixels which share a same second initial signal line 49, 10 third transfer connection electrodes 61 are provided in space of each column of pixels, and one fourth transfer connection electrode 62 is located between two columns of pixels. Six first transfer connection electrodes 51 and one second transfer connection electrode 52 are provided in space of a same row of pixels.

In an exemplary implementation, as shown in FIG. 15d, a pixel may include three sub-pixels. Three columns of sub-pixels, three data signal lines 48, and nine third transfer connection electrodes 61 are provided in space of a same column of pixels, and the three columns of sub-pixels are respectively connected to the three data signal lines 48. Six first transfer connection electrodes 51 are provided in space of a same row of pixels.

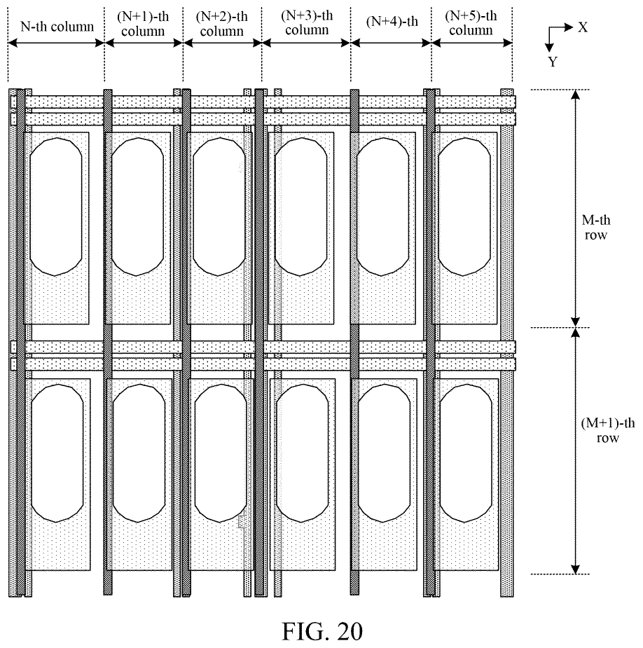

In an exemplary implementation, as shown in FIG. 20, a pixel may include three sub-pixels. Three columns of sub-pixels, three data signal lines 48, and three third transfer connection electrodes 61 are provided in space of a same column of pixels, and the three columns of sub-pixels are respectively connected to the three data signal lines 48. Two first transfer connection electrodes 51 are provided in space of a same row of pixels.

In an exemplary implementation, as shown in FIG. 13a, a sub-pixel may include a first transistor T1 to a fifth transistor T5 and a storage capacitor. The second transistor T2, the first transistor T1, the third transistor T3, the fourth transistor T4, and the fifth transistor T5 are arranged in a second direction Y in a plane parallel to the display substrate. An orthographic projection of the storage capacitor on the base substrate is overlapped with an orthographic projection of the third transistor T3 on the base substrate. In a same pixel, two adjacent sub-pixels are symmetrically arranged with respect to a first center line, and the first center line is a center line of the two adjacent sub-pixels extending in the second direction Y.

In an exemplary implementation, as shown in FIG. 13a, a plurality of sub-pixel groups Z may be included in a same column of sub-pixels. Each sub-pixel group may include two adjacent sub-pixels, and two sub-pixels in a same sub-pixel group Z share a same fifth transistor T5, which can reduce the quantity of transistors and save space of the display substrate. In an embodiment of the present disclosure, in a same pixel column, four sub-pixels in two adjacent sub-pixel groups may be located in four rows of sub-pixels. In the same pixel column, two adjacent sub-pixels located in two adjacent sub-pixel groups Z do not share a fifth transistor T5, and two sub-pixels located in the same sub-pixel group Z may share a fifth transistor T5.

In an exemplary implementation, at least one sub-pixel may include a pixel drive circuit, and the pixel drive circuit may include a plurality of oxide transistors and a storage capacitor. In a plane perpendicular to the display substrate, the display substrate includes a base substrate, and a semiconductor layer, a first conductive layer, a second conductive layer, a third conductive layer, a fourth conductive layer and a fifth conductive layer which are stacked sequentially on the base substrate.

The semiconductor layer includes active layers of a plurality of oxide transistors.

The first conductive layer includes control electrodes of the plurality of oxide transistors and a first plate of the storage capacitor.

The second conductive layer includes a second plate of the storage capacitor.

The third conductive layer includes a plurality of data signal lines 48, and first and second electrodes of the plurality of oxide transistors, and the data signal lines 48 extend in a second direction Y.

The fourth conductive layer includes a plurality of first transfer connection electrodes 51 extending in a first direction X.

The fifth conductive layer includes a plurality of third transfer connection electrodes 61 extending in the second direction Y, and the first direction X intersects the second direction Y in a plane parallel to the display substrate.

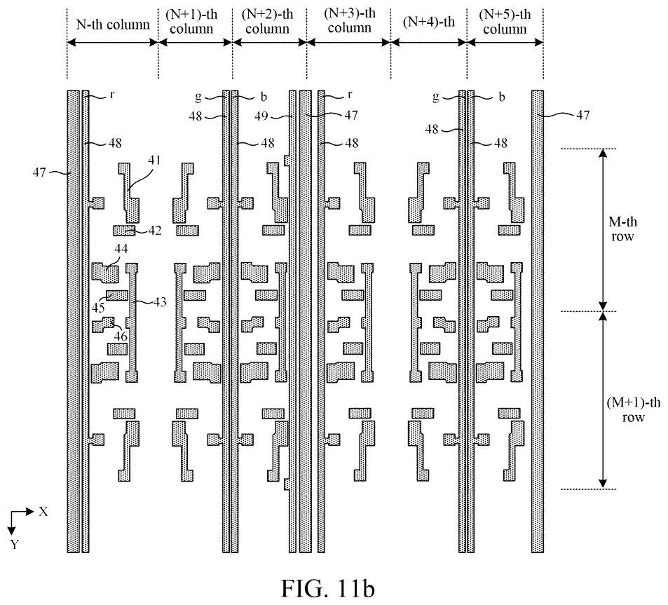

In an exemplary implementation, as shown in FIG. 11b, the third conductive layer may further include a plurality of second initial signal lines 49 extending in the second direction Y. Two adjacent columns of pixels share a same second initial signal line 49. A plurality of data signal lines 48 in two columns of pixels sharing one second initial signal line 49 are symmetrical with respect to the second initial signal line 49.

As shown in FIG. 13b, the fourth conductive layer may further include a plurality of second transfer connection electrodes 52 extending in the first direction X. A plurality of second transfer connection electrodes 52 located in the second display area AA2 are electrically connected to a plurality of second initial signal lines 49 respectively.

As shown in FIG. 15b, the fifth conductive layer may further include a plurality of fourth transfer connection electrodes 62 extending in the second direction Y. The plurality of fourth transfer connection electrodes 62 are electrically connected to a plurality of second transfer connection electrodes 52 located in the second display area AA2, respectively.

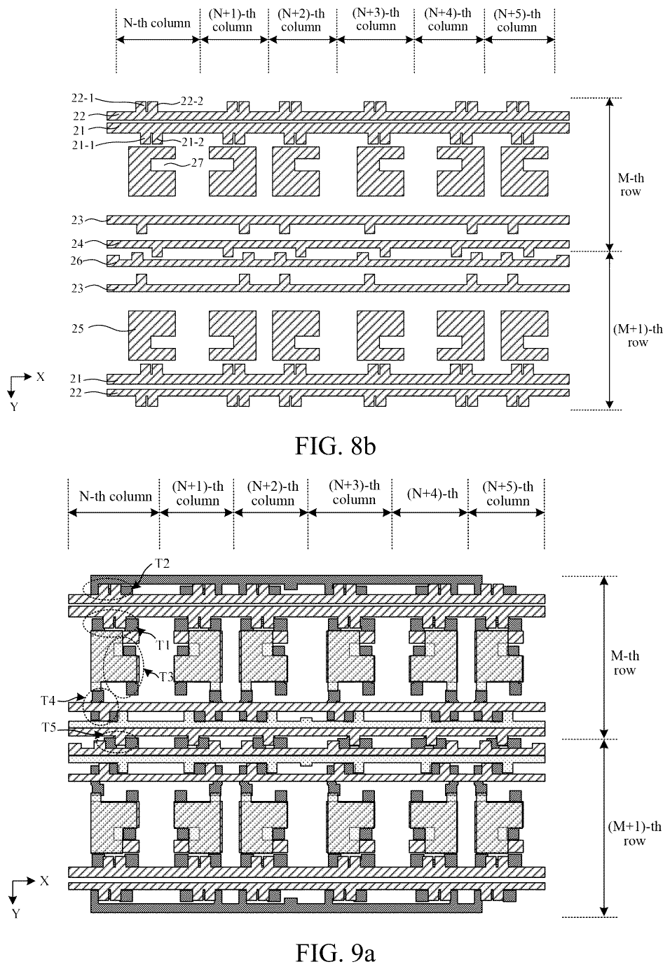

In an exemplary implementation, as shown in FIG. 8b, the first conductive layer may further include a plurality of first power supply connection lines 26 extending in the first direction X. As shown in FIG. 13a, a plurality of sub-pixel groups Z may be included in a same column of sub-pixels. Each sub-pixel group Z may include two adjacent sub-pixels. In the same sub-pixel group Z, two sub-pixels share a same first power supply connection line 26, and the two sub-pixels in the same sub-pixel group Z may be symmetrical with respect to the first power supply connection line 26.

As shown in FIG. 11b, the third conductive layer may further include first power supply lines 47 extending in the second direction Y. The first power supply lines 47 may be electrically connected to first power supply connection lines 26 through vias.

In an exemplary implementation, as shown in FIG. 5, a shape of the display substrate may be a heart shape. The display area AA may include a first display area AA1 and a second display area AA2. The bonding area 10 may be located on one side of the display area AA, and the first display area AA1, the second display area AA2, and the bonding area 10 may be sequentially arranged along the second direction Y.

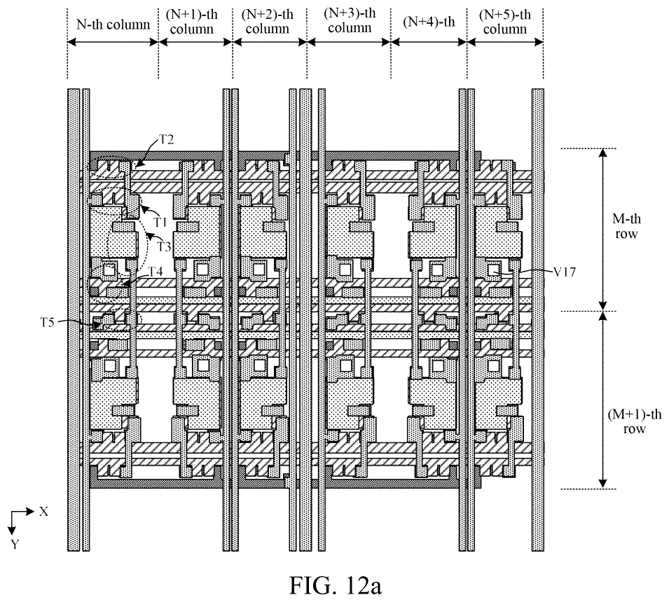

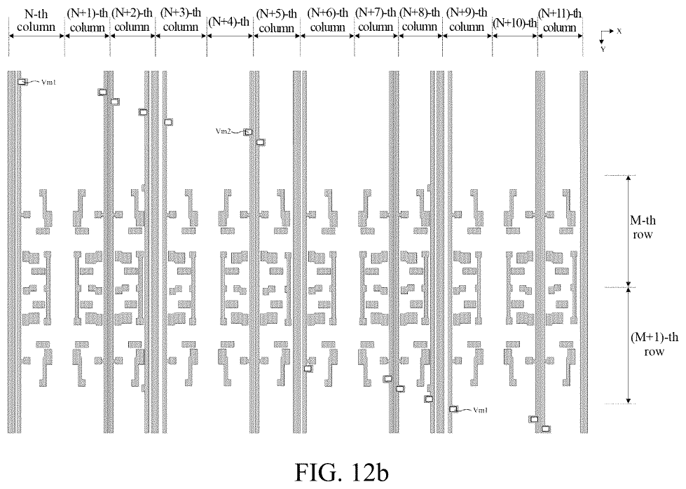

In an exemplary implementation, as shown in FIGS. 12b, 13c, 14, 15c, and 21, at least a part of the first transfer connection electrodes 51 may be electrically connected to a plurality of data signal lines 48 through a plurality of first transfer vias Vm1, respectively. At least a part of the third transfer connection electrodes 61 may be electrically connected to at least a part of the first transfer connection electrodes 51 through a plurality of third transfer vias Vm3, respectively. An arrangement direction of the plurality of first transfer vias Vm1 forms a first included angle F1 with a center line Q1-Q1 of the display substrate extending in the second direction Y, and an arrangement direction of the plurality of third transfer holes Vm3 forms a second included angle F2 with the center line Q1-Q1 of the display substrate extending in the second direction Y.

In an exemplary implementation, the first included angle F1 ranges from 30 degrees to 60 degrees, and the second included angle F2 ranges from 15 degrees to 45 degrees. For example, the first included angle F1 may be 45 degrees, and the second included angle F2 may be 30 degrees.

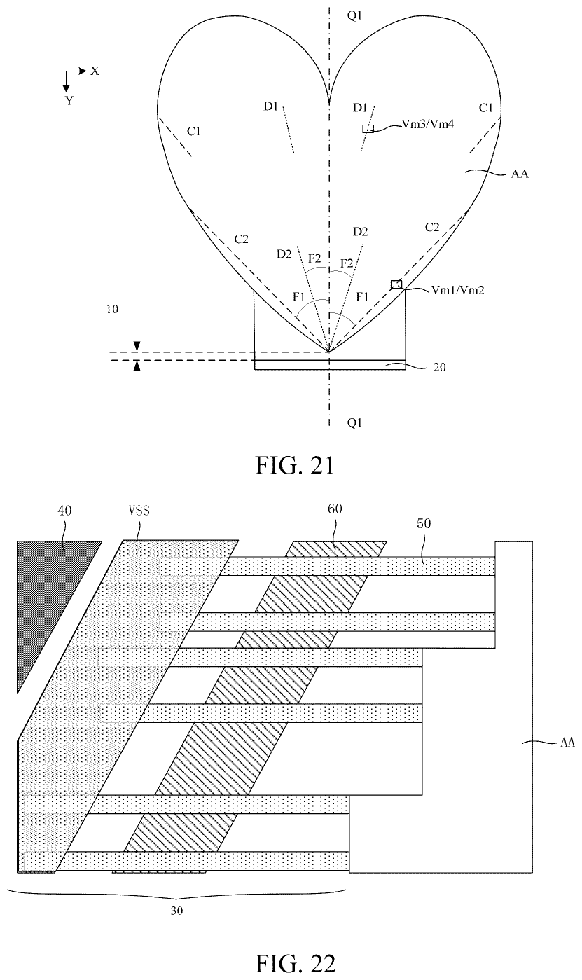

In an exemplary implementation, as shown in FIG. 21, the arrangement direction of the plurality of first transfer vias Vm1 may be symmetrically provided with respect to the center line Q1-Q1 of the display substrate extending in the second direction Y, and the arrangement direction of the plurality of third transfer vias Vm3 may be symmetrically provided with respect to the center line Q1-Q1 of the display substrate extending in the second direction Y.

In an exemplary implementation, as shown in FIG. 21, in a display area AA located on one side of the center line of the display substrate extending in the second direction Y, a plurality of first transfer vias Vm1 are arranged in at least two directions, and the at least two arrangement directions are parallel to each other. Connection lines C1 and C2 of the plurality of first transfer vias Vm1 located in the at least two arrangement directions are arranged in the second direction Y. A plurality of third transfer vias Vm3 are arranged in at least two directions, and the at least two arrangement directions are parallel to each other. Connection lines D1 and D2 of the plurality of third transfer vias Vm3 located in the at least two arrangement directions are arranged in the second direction Y.

In an exemplary implementation, as shown in FIGS. 13a to 15d, the fourth conductive layer may further include anode connection electrodes 53 electrically connected to a plurality of sub-pixels respectively. Orthographic projections of the first transfer connection electrodes 51 and the third transfer connection electrodes 61 on the base substrate are not overlapped with orthographic projections of a plurality of anode connection electrodes 53 on the base substrate, so as to avoid blocking anodes to be formed subsequently.

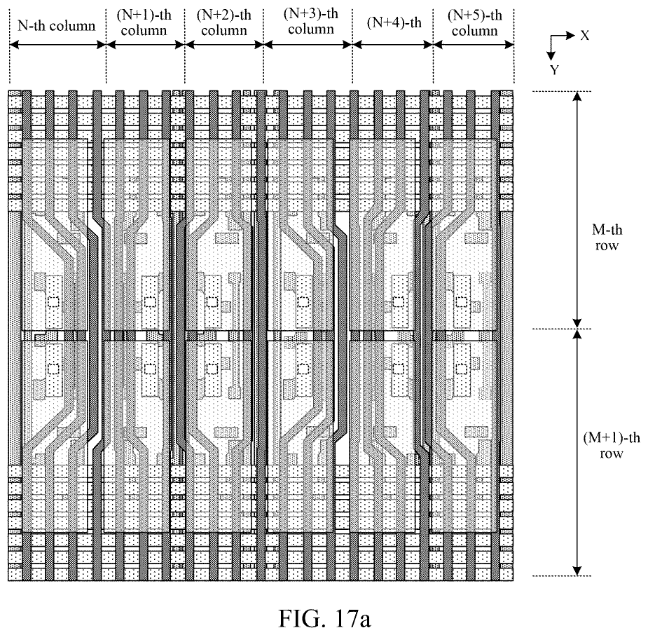

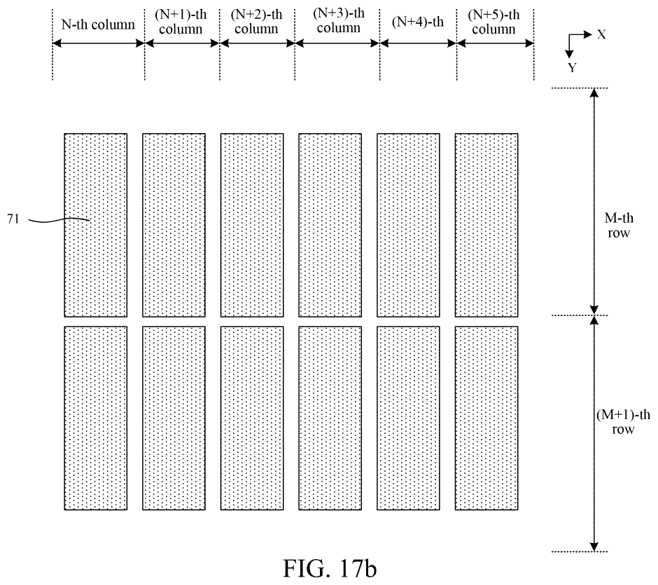

In an exemplary implementation, as shown in FIGS. 6a, 17a, and 17b, the display substrate may further include an anode conductive layer. The anode conductive layer may include a plurality of anodes 71, and the plurality of anodes 71 are respectively connected to a plurality of anode connection electrodes 53. In a same pixel, orthographic projections of a plurality of anodes 71 on the base substrate and orthographic projections of a plurality of first transfer connection electrodes 51 and a plurality of third transfer connection electrodes 61 on the base substrate have a first overlapping region therebetween. The plurality of pixels correspond to a plurality of first overlapping regions. Areas of the plurality of first overlapping regions are consistent, so that the segment differences of the plurality of anodes 71 can be kept consistent, and the problem of non-uniform light emission due to inconsistent segment differences of the anodes can be avoided. For example, areas of the plurality of first overlapping regions may be identical.

In an exemplary implementation, as shown in FIG. 5, the display substrate may include a bezel BB located around the display area AA. The bezel BB may include a first bezel BB1 and a second bezel BB2, herein the bonding area 10 may be located in the first bezel BB1 (i.e., a lower bezel).

In an exemplary implementation, as shown in FIG. 5, a size of the bonding area 10 along the first direction X may be smaller than a size of the display area AA along the first direction X. The plurality of third transfer connection electrodes 61 may include two parts, wherein a part of third transfer connection electrodes 61 extend to the bonding area 10 and another part of third transfer connection electrodes 61 do not extend to the bonding area 10. Herein, a plurality of third transfer connection electrodes 61 extending to the bonding area 10 are electrically connected to a plurality of first transfer connection electrodes 51 located in the second display area AA2 respectively. In an exemplary implementation, a plurality of third transfer connection electrodes 61 not extending to the bonding area 10 may not be electrically connected to the plurality of first transfer connection electrodes 51 located in the second display area AA2. In an exemplary implementation, the plurality of third transfer connection electrodes 61 extending to the bonding area 10 are electrically connected to the bonding area, and the plurality of third transfer connection electrodes 61 not extending to the bonding area 10 may not be electrically connected to the bonding area 10. The plurality of third transfer connection electrodes 61 not extending to the bonding region 10 and a plurality of first transfer connection electrodes 51 located in the first display area AA1 may not participate in signal transmission, but may play a role in improving the consistency of traces under anodes of a plurality of pixels and avoiding the non-uniform light emission due to inconsistent segment differences of anodes.

In some other implementations, the size of the bonding area 10 along the first direction X may be not smaller than the size of the display area AA along the first direction X, and an arrangement mode of the bonding area 10 may be determined according to the shape of the display substrate.

Exemplary description is made below through a preparation process of a display substrate. A “patterning process” mentioned in the present disclosure includes photoresist coating, mask exposure, development, etching, photoresist stripping, etc., for a metal material, an inorganic material, or a transparent conductive material, and includes organic material coating, mask exposure, development, etc., for an organic material. Deposition may be any one or more of sputtering, evaporation, and chemical vapor deposition, coating may be any one or more of spray coating, spin coating, and inkjet printing, and etching may be any one or more of dry etching and wet etching, the present disclosure is not limited thereto. A “thin film” refers to a layer of thin film made of a material on a base substrate (or substrate) using deposition, coating, or other processes. If the “thin film” does not need to be processed through a patterning process in the entire manufacturing process, the “thin film” may also be referred to as a “layer”. If the “thin film” needs to be processed through the patterning process in the entire manufacturing process, the “thin film” is called a “thin film” before the patterning process is performed and is called a “layer” after the patterning process is performed. At least one “pattern” is contained in the “layer” which has been processed through the patterning process. “A and B are disposed in a same layer” in the present disclosure means that A and B are formed simultaneously through a same patterning process, and a “thickness” of a film layer is a dimension of the film layer in a direction perpendicular to a display substrate. In an exemplary implementation of the present disclosure, “an orthographic projection of B being within a range of an orthographic projection of A” or “an orthographic projection of A containing an orthographic projection of B” means that a boundary of the orthographic projection of B falls within a range of a boundary of the orthographic projection of A, or the boundary of the orthographic projection of A is overlapped with the boundary of the orthographic projection of B.

In an exemplary implementation, taking 12 sub-pixels (in 2 sub-pixel rows and 6 sub-pixel columns) in a display area (AA) as an example, a manufacturing process of a display substrate may include following operations.

(101) A base substrate is prepared on a glass carrier plate. In an exemplary implementation, the base substrate may be a flexible substrate, or a rigid substrate. The rigid substrate may include, but is not limited to, one or more of glass and quartz. The flexible substrate may be, but is not limited to, one or more of polyethylene terephthalate, polyether ether ketone, polystyrene, polycarbonate, polyarylate, polyarylester, polyimide, polyvinyl chloride, polyethylene, and textile fiber. In an exemplary implementation, the flexible substrate may include a first flexible material layer, a first inorganic material layer, an adhesive layer, a second flexible material layer, and a second inorganic material layer which are stacked. Materials of the first flexible material layer and the second flexible material layer may be Polyimide (PI), Polyethylene Terephthalate (PET), or a polymer soft thin film subjected to surface treatment, etc. Materials of the first inorganic material layer and the second inorganic material layer may be Silicon Nitride (SiNx), Silicon Oxide (SiOx), or the like, so as to improve a water-oxygen resistance capability of the base substrate. The first inorganic material layer and the second inorganic material layer are also referred to as barrier layers. A material of the adhesive layer may be amorphous silicon (a-si). In an exemplary implementation, taking a stacked structure PI1/Barrier1/a-si/PI2/Barrier2 as an example, its manufacturing process may include: firstly coating a layer of polyimide on a glass carrier board, and curing it into a film to form a first flexible material (PI1) layer; then depositing a layer of barrier thin film on the first flexible layer to form a first barrier (Barrier1) layer overlying the first flexible material layer; then depositing a layer of amorphous silicon thin film on the first barrier layer to form an amorphous silicon (a-si) layer overlying the first barrier layer; then coating a layer of polyimide on the amorphous silicon layer, and curing it into a film to form a second flexible material (PI2) layer; and then depositing a barrier thin film on the second flexible layer to form a second barrier (Barrier2) layer overlying the second flexible layer, thus completing the manufacturing of the base substrate.

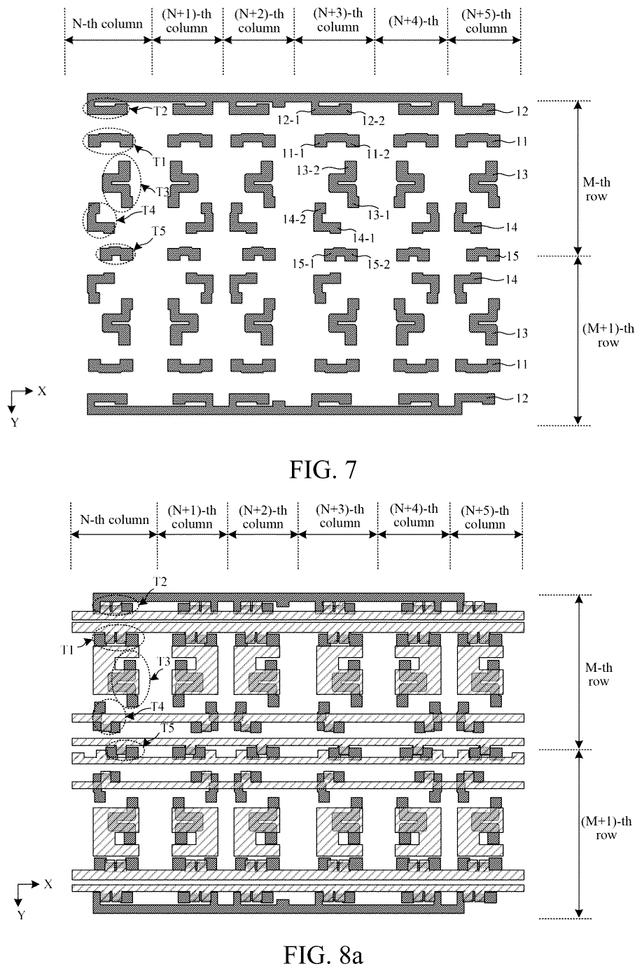

(102) A pattern of a semiconductor layer is formed. In an exemplary implementation, forming the pattern of the semiconductor layer may include: sequentially depositing a first insulation thin film and a semiconductor thin film on the base substrate, patterning the semiconductor thin film through a patterning process to form a pattern of a semiconductor layer disposed on the first insulation layer, as shown in FIG. 7. FIG. 7 is a schematic diagram of a planar structure of the semiconductor layer in twelve sub-pixels.

In an exemplary implementation, the pattern of the semiconductor layer of each sub-pixel may include an active layer 11 of a first transistor T1 to an active layer 15 of a fifth transistor T5.

In an exemplary implementation, in the second direction Y, in the same sub-pixel, an active layer 12 of a second transistor T2, the active layer 11 of the first transistor T1, an active layer 13 of a third transistor T3, an active layer 14 of a fourth transistor T4, and the active layer of the fifth transistor T5 are sequentially arranged.

In an exemplary implementation, the active layer 13 of the third transistor T3 may in a shape of an “2”, the active layer 11 of the first transistor T1 and the active layer 15 of the fifth transistor T5 may in a shape of a “n”, and an active layer 12 facing away from the second transistor T2 is provided, and the active layer 12 of the second transistor T2 and the active layer 14 of the fourth transistor T4 may be in a shape of a “L”.

In an exemplary implementation, an active layer of each transistor may include a first region, a second region, and a channel region located between the first region and the second region. In an exemplary implementation, first regions 11-1 of active layers 12 of a plurality of second transistors T2 located in a same sub-pixel row may be connected to each other so that the active layers 12 of the plurality of second transistors T2 located in the same sub-pixel row are formed into an integrated structure. In an exemplary implementation, since a first region of an active layer of a second transistor T2 in each sub-pixel is connected to a second initial signal line to be formed subsequently, by forming first regions of active layers of second transistors T2 of a same sub-pixel row into an interconnected integrated structure, first electrodes of second transistors T2 in adjacent sub-pixels may be ensured to have a same potential, which is beneficial to improving display uniformity of a panel and avoiding poor display of the display substrate, thereby ensuring a display effect of the display substrate.

In an exemplary implementation, two adjacent sub-pixels located in a same sub-pixel column may share a fifth transistor T5. For example, a sub-pixel in an M-th row and a sub-pixel in an (M+1)-th row in an N-th column may share a fifth transistor T5, and the sub-pixel in the M-th row and the sub-pixel in the (M+1)-th row in the N-th column may share an active layer 15 of the fifth transistor T5 to save layout space. In an exemplary implementation, a plurality of sub-pixel groups may be included in a same sub-pixel column, each sub-pixel group may include a sub-pixel in an odd-numbered row and a sub-pixel in an even-numbered row, and four sub-pixels in two adjacent sub-pixel groups are located in four sub-pixel rows.

In an exemplary implementation, a semiconductor layer in an N-th column and a semiconductor layer in an (N+1)-th column may be mirror symmetrical with respect to a first center line, a semiconductor layer in an (N+1)-th column and a semiconductor layer in an (N+2)-th column may be mirror symmetrical with respect to a second center line, and a semiconductor layer in an (N+3)-th column and a semiconductor layer in an (N+4)-th column may be mirror symmetrical with respect to a third center line. The semiconductor layer in the (N+4)-th column and a semiconductor layer in an (N+5)-th column may be mirror symmetrical with respect to a fourth center line. The first center line is a center line of the semiconductor layer in the N-th column and the semiconductor layer in the (N+1)-th column extending in the second direction Y, the second center line is a center line of the semiconductor layer in the (N+1)-th column and the semiconductor layer in the (N+2)-th column extending in the second direction Y, the third center line is a center line of the semiconductor layer in the (N+3)-th column and the semiconductor layer in the (N+4)-th column extending in the second direction Y, and the fourth center line is a center line of the semiconductor layer in the (N+4)-th column and the semiconductor layer in the (N+5)-th column extending in the second direction Y.

In an exemplary implementation, the semiconductor layer may be made of an oxide, that is, the first transistor T1 to the fifth transistor T5 are oxide thin film transistors. In an exemplary implementation, the oxide may be any one or more of following: Indium Gallium Zinc Oxide (InGaZnO), Indium Gallium Zinc Oxynitride (InGaZnON), Zinc Oxide (ZnO), Zinc Oxynitride (ZnON), Zinc Tin Oxide (ZnSnO), Cadmium Tin Oxide (CdSnO), Gallium Tin Oxide (GaSnO), Titanium Tin Oxide (TiSnO), Copper Aluminum Oxide (CuAlO), Strontium Copper Oxide (SrCuO), Lanthanum Copper Sulfur Oxide (LaCuOS), Gallium Nitride (GaN), Indium Gallium Nitride (InGaN), Aluminum Gallium Nitride (AlGaN), and Indium Gallium Aluminum Nitride (InGaAlN). In some possible implementations, the semiconductor thin film may be made of Indium Gallium Zinc Oxide (IGZO), an electron mobility of Indium Gallium Zinc Oxide (IGZO) is higher than an electron mobility of amorphous silicon.

(103) A pattern of a first conductive layer is formed. In an exemplary implementation, forming the pattern of the first conductive layer may include: sequentially depositing a second insulating thin film and a first conductive thin film on the base substrate on which the above-mentioned pattern is formed, and patterning the first conductive thin film through a patterning process to form a second insulation layer that covers the pattern of the semiconductor layer and form the pattern of the first conductive layer disposed on the second insulation layer, as shown in FIG. 8a and FIG. 8b. FIG. 8b is a schematic plan view of the first conductive layer in FIG. 8a. In an exemplary implementation, the first conductive layer may be referred to as a first gate metal (GATE1) layer.

In an exemplary implementation, the pattern of the first conductive layer may include at least a first scan signal line 21, a second scan signal line 22, a third scan signal line 23, a light emission control line 24, a first plate 25 of a storage capacitor, and a first power supply connection line 26. The main body portion of the second scan signal line 22, the first scan signal line 21, the third scan signal line 23, the light emission control line 24, and the first power supply connection line 26 may extend in the first direction X. In a same sub-pixel, the second scan signal line 22, the first scan signal line 21, the first plate 25 of the storage capacitor, and the third scan signal line 23 are arranged in the second direction Y, and the light emission control line 24 and the first power supply connection line 26 are arranged in the second direction Y.

In an exemplary implementation, sub-pixels in two adjacent rows may share a light emission control line 24 and a first power supply connection line 26, and the light emission control line 24 and the first power supply connection line 26 may be located between third scan signal lines 23 of the two adjacent rows of sub-pixels. In an exemplary implementation, two adjacent sub-pixels located in a same sub-pixel column may share a fifth transistor T5. For example, a sub-pixel in an M-th row and a sub-pixel in an (M+1)-th row in an N-th column may share a fifth transistor T5, and the sub-pixel in the M-th row and the sub-pixel in the (M+1)-th row may share a light emission control line 24 and a first power supply connection line 26 to save layout space.

Take a sub-pixel in the M-th row and the N-th column as an example, in the second direction Y, the first scan signal line 21 may be located on a side of the first plate 25 of the storage capacitor away from sub-pixels in the (M+1)-th row, the second scan signal line 22 may be located on a side of the first scan signal line 21 away from the first plate 25 of the storage capacitor, the third scan signal line 23 may be located on a side of the first plate 25 of the storage capacitor away from the first scan signal line 21, the light emission control line 24 may be located on a side of the third scan signal line 23 away from the first plate 25 of the storage capacitor, and the first power supply connection line 26 may be located on a side of the light emission control line 24 away from the third scan signal line 23.

In an exemplary implementation, the first plate 25 may be located between the third scan signal line 23 and the first scan signal line 21. The first plate 25 may have a rectangular shape, and an orthographic projection of the first plate 25 on the base substrate is overlapped with an orthographic projection of the active layer of the third transistor T3 on the base substrate. In an exemplary embodiment, the first plate 25 may simultaneously serve as a plate of the storage capacitor and the control electrode of the third transistor T3. In an exemplary implementation, the first plate 25 may be provided with an opening 27. The opening 27 may be located at an edge position of the first plate 25. The opening 27 may be rectangular, so that the first plate 25 forms an n-shaped structure. An orthographic projection of the opening 27 on the base substrate is overlapped with an orthographic projection of the second region 13-2 of the active layer 13 of the third transistor T3 on the base substrate. In an exemplary embodiment, the opening 27 is configured to accommodate a fifth via to be formed subsequently. The fifth via is within the opening 27 and exposes the second region 13-2 of the active layer 13 of the third transistor T3, so that a second electrode of the third transistor T3 to be formed subsequently is connected to the second region 13-2 of the active layer 13 of the third transistor T3.

In an exemplary implementation, a region where the light emission control line 24 overlaps the active layer of the fifth transistor T5 serves as the control electrode of the fifth transistor T5. A region where the first scan signal line 21 overlaps the active layer of the first transistor T1 serves as the control electrode of the first transistor T1. A region where the second scan signal line 22 overlaps the active layer of the second transistor T2 serves as the control electrode of the second transistor T2. A region where the third scan signal line 23 overlaps the active layer of the fourth transistor T4 serves as the control electrode of the fourth transistor T4. In an exemplary implementation, the first scan signal line 21 is provided with a first convex portion 21-1 and a second convex portion 21-2, the first convex portion 21-1 and the second convex portion 21-2 are arranged in the first direction X, and the first convex portion 21-1 and the second convex portion 21-2 are both overlapped with the active layer of the first transistor T1, so that the first transistor T1 forms a double-gate structure. In an exemplary implementation, the second scan signal line 22 is provided with a first convex structure 22-1 and a second convex structure 22-2. The first convex structure 22-1 and the second convex structure 22-2 are arranged in the first direction X, and the first convex structure 22-1 and the second convex structure 22-2 are both overlapped with the active layer of the second transistor T2, so that the second transistor T2 forms a double-gate structure. The first transistor T1 and the second transistor T2 in an embodiment of the present disclosure are dual-channel transistors.

In an exemplary implementation, the first scan signal line 21, the second scan signal line 22, the third scan signal line 23, the light emission control line 24 and the first power supply connection line 26 may have an equal width design or non-equal width design, thereby not only a layout of a pixel structure may be facilitated, but also a parasitic capacitance between signal lines may be reduced.

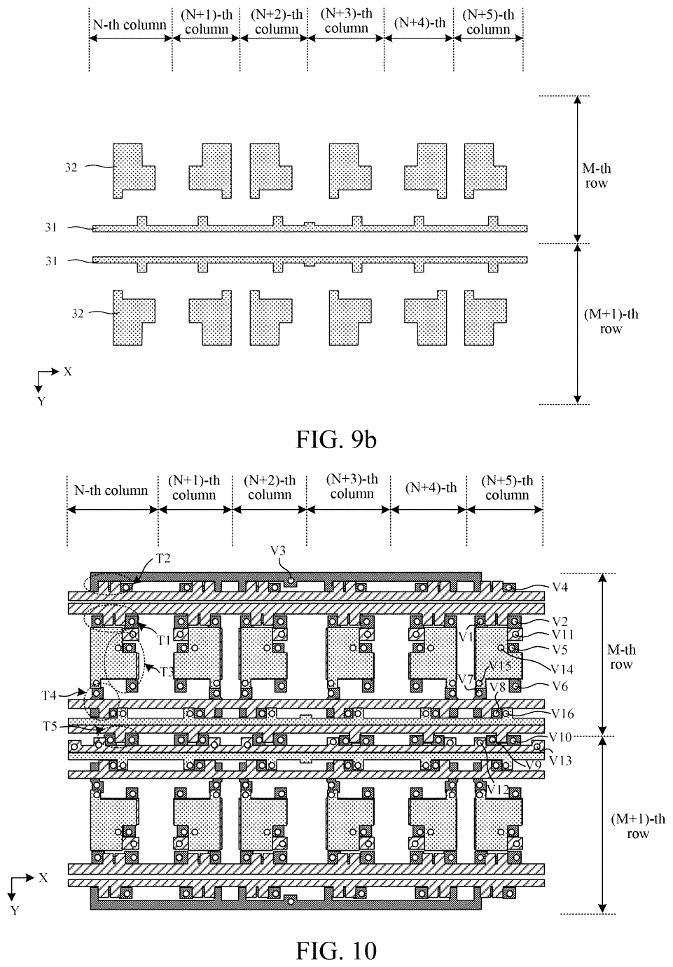

(104) A pattern of a second conductive layer is formed. In an exemplary implementation, forming the pattern of the second conductive layer may include: depositing sequentially a third insulation thin film and a second conductive thin film on the base substrate where the aforementioned patterns are formed, and patterning the second conductive thin film through a patterning process to form a third insulation layer covering the first conductive layer and the pattern of the second conductive layer disposed on the third insulation layer, as shown in FIG. 9a and FIG. 9b. FIG. 9a is a schematic diagram of a planar structure of twelve sub-pixels, and FIG. 9b is a schematic plan view of the second conductive layer in FIG. 9a. In an exemplary implementation, the second conductive layer may be referred to as a second gate metal (GATE2) layer.

In an exemplary implementation, the pattern of the second conductive layer includes at least a first initial signal line 31 and a second plate 32 of a storage capacitor, and a main body portion of the first initial signal line 31 may extend in the first direction X. The second plate 32 of the storage capacitor serves as the other plate of the storage capacitor.

In an exemplary implementation, in a same sub-pixel group and in the second direction Y, in one of the sub-pixels, the second plate 32 of the storage capacitor and the first initial signal line 31 are sequentially arranged in the second direction Y, and in another sub-pixel, the second plate 32 of the storage capacitor and the first initial signal line 31 are sequentially arranged in an opposite direction of the second direction Y. For example, in a sub-pixel in an M-th row and an N-th column, the second plate 32 of the storage capacitor and the first initial signal line 31 are sequentially arranged in the second direction Y. In a sub-pixel in an (M+1)-th row and an N-th column, the second plate 32 of the storage capacitor and the first initial signal line 31 are sequentially arranged in the opposite direction of the second direction Y.

In an exemplary implementation, a profile of second plate 32 may be rectangular. An orthographic projection of the second plate 32 on the base substrate is overlapped with an orthographic projection of the first plate 25 on the base substrate. The first plate 25 and the second plate 32 form the storage capacitor of the pixel drive circuit.

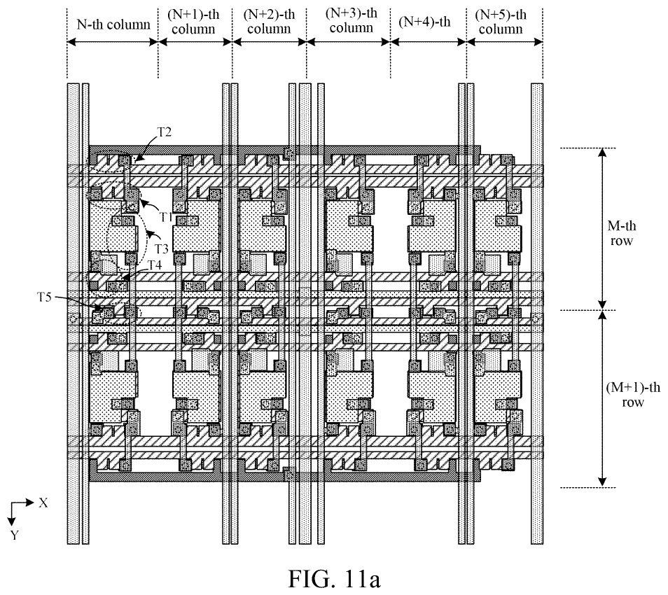

(105) A pattern of a fourth insulation layer is formed. In an exemplary embodiment, forming the pattern of the fourth insulation layer may include: depositing a fourth insulation thin film on the base substrate on which the aforementioned patterns are formed, and patterning the fourth insulation thin film through a patterning process to form a fourth insulation layer covering the second conductive layer, wherein the fourth insulation layer is provided with a plurality of vias, as shown in FIG. 10. FIG. 10 is a diagram of a planar structure of twelve sub-pixels.

In an exemplary implementation, the plurality of vias of each sub-pixel at least include: a first via V1, a second via V2, a third via V3, a fourth via V4, a fifth via V5, a sixth via V6, a seventh via V7, an eighth via V8, a ninth via V9, a tenth via V10 and an eleventh via V11, a twelfth via V12, a thirteenth via V13, a fourteenth via V14, a fifteenth via V15, and a sixteenth via V16.

In an exemplary implementation, an orthographic projection of the first via V1 on the base substrate is within a range of an orthographic projection of the active layer 11 of the first transistor T1 on the base substrate. The fourth insulation layer, the third insulation layer and the second insulation layer in the first via V1 are etched away to expose a surface of a first region 11-1 of the active layer 11 of the first transistor T1. The first via V1 is configured so that the first electrode of the first transistor T1 to be formed subsequently is connected to the active layer 11 of the first transistor T1 through this via.

In an exemplary implementation, an orthographic projection of the second via V2 on the base substrate is within a range of an orthographic projection of the active layer 11 of the first transistor T1 on the base substrate. The fourth insulation layer, the third insulation layer and the second insulation layer in the second via V2 are etched away to expose a surface of a second region 11-2 of the active layer 11 of the first transistor T1. The second via V2 is configured so that the second electrode of the first transistor T1 to be formed subsequently is connected to the active layer 11 of the first transistor T1 through the second via V2.

In an exemplary implementation, an orthographic projection of the third via V3 on the base substrate is within a range of an orthographic projection of the active layer 12 of the second transistor T2 on the base substrate. The fourth insulation layer, the third insulation layer and the second insulation layer in the third via V3 are etched away to expose a surface of a first region 22-1 of the active layer 12 of the second transistor T2. The third via V3 is configured such that a first initial signal line to be formed subsequently is connected to the active layer 12 of the second transistor T2 through the third via V3.

In an exemplary implementation, an orthographic projection of the fourth via V4 on the base substrate is within a range of an orthographic projection of the active layer 12 of the second transistor T2 on the base substrate. The fourth insulation layer, the third insulation layer and the second insulation layer in the fourth via V4 are etched away to expose a second region 12-2 of the active layer 12 of the second transistor T2. The fourth via V4 is configured such that the second electrode of the second transistor T2 to be formed subsequently is connected to the active layer 12 of the second transistor T2 through the fourth via V4.

In an exemplary implementation, an orthographic projection of the fifth via V5 on the base substrate is within a range of an orthographic projection of the active layer 13 of the third transistor T3 on the base substrate. The fourth insulation layer, the third insulation layer and the second insulation layer in the fifth via V5 are etched away to expose a surface of a second region 13-2 of the active layer 13 of the third transistor T3. The fifth via V5 is configured such that the second electrode of the third transistor T3 to be formed subsequently is connected to the active layer 13 of the third transistor T3 through the fifth via V5.

In an exemplary implementation, an orthographic projection of the sixth via V6 on the base substrate is within a range of an orthographic projection of the active layer 13 of the third transistor T3 on the base substrate. The fourth insulation layer, the third insulation layer and the second insulation layer in the sixth via V6 are etched away to expose a surface of a first region 13-1 of the active layer 13 of the third transistor T3. The sixth via V6 is configured such that the first electrode of the third transistor T3 to be formed subsequently is connected to the active layer 13 of the third transistor T3 through the sixth via V6.

In an exemplary implementation, an orthographic projection of the seventh via V7 on the base substrate is within a range of an orthographic projection of the active layer 14 of the fourth transistor T4 on the base substrate. The fourth insulation layer, the third insulation layer and the second insulation layer in the seventh via V7 are etched away to expose a surface of a second region 14-2 of the active layer 14 of the fourth transistor T4. The seventh via V7 is configured such that the second electrode of the fourth transistor T4 to be formed subsequently is connected to the active layer 14 of the fourth transistor T4 through the seventh via V7.

In an exemplary implementation, an orthographic projection of the eighth via V8 on the base substrate is within a range of an orthographic projection of the active layer 14 of the fourth transistor T4 on the base substrate. The fourth insulation layer, the third insulation layer and the second insulation layer in the eighth via V8 are etched away to expose a surface of a first region 14-1 of the active layer 14 of the fourth transistor T4. The eighth via V8 is configured such that the first electrode of the fourth transistor T4 to be formed subsequently is connected to the active layer 14 of the fourth transistor T4 through the eighth via V8.

In an exemplary implementation, an orthographic projection of the ninth via V9 on the base substrate is within a range of an orthographic projection of the active layer 15 of the fifth transistor T5 on the base substrate. The fourth insulation layer, the third insulation layer and the second insulation layer in the ninth via V9 are etched away to expose a surface of a first region 15-1 of the active layer 15 of the fifth transistor T5. The ninth via V9 is configured such that the first electrode of the fifth transistor T5 to be formed subsequently is connected to the active layer 15 of the fifth transistor T5 through the ninth via V9.

In an exemplary implementation, an orthographic projection of the tenth via V10 on the base substrate is within a range of an orthographic projection of the active layer 15 of the fifth transistor T5 on the base substrate. The fourth insulation layer, the third insulation layer and the second insulation layer in the tenth via V10 are etched away to expose a surface of a second region 15-2 of the active layer 15 of the fifth transistor T5. The tenth via V10 is configured such that the second electrode of the fifth transistor T5 to be formed subsequently is connected to the active layer 15 of the fifth transistor T5 through the tenth via V10.

In an exemplary implementation, an orthographic projection of the eleventh via V11 on the base substrate is within a range of an orthographic projection of the first plate 25 on the base substrate. The fourth insulation layer and the third insulation layer in the eleventh via V11 are etched away to expose a surface of the first plate 25 of the storage capacitor. The eleventh via V11 is configured such that the second electrode of the third transistor T3 to be formed subsequently is connected to the first plate 25 of the storage capacitor through the eleventh via V11.

In an exemplary implementation, an orthographic projection of the twelfth via V12 on the base substrate is within a range of an orthographic projection of the first power supply connection line 26 on the base substrate. The fourth insulation layer and the third insulation layer in the twelfth via V12 are etched away to expose a surface of the first power supply connection line 26. The twelfth via V12 is configured such that a first electrode of the fifth transistor T5 to be formed subsequently is connected to the first power supply connection line 26 through the twelfth via V12.

In an exemplary implementation, an orthographic projection of the thirteenth via V13 on the base substrate is within a range of an orthographic projection of the first power supply connection line 26 on the base substrate. The fourth insulation layer and the third insulation layer in the thirteenth via V13 are etched away to expose a surface of the first power supply connection line 26. The thirteenth via V13 is configured such that the first power supply line to be formed subsequently is connected to the first power supply connection line 26 through the thirteenth via V13.

In an exemplary implementation, an orthographic projection of the fourteenth via V14 on the base substrate is within a range of an orthographic projection of the second plate 32 of the storage capacitor on the base substrate. The fourth insulation layer in the fourteenth via V14 is etched away to expose a surface of the second plate 32 of the storage capacitor. The fourteenth via V14 is configured such that the second electrode of the third transistor T3 to be formed subsequently is connected to the second plate 32 of the storage capacitor.

In an exemplary implementation, an orthographic projection of the fifteenth via V15 on the base substrate is within a range of an orthographic projection of the second plate 32 of the storage capacitor on the base substrate. The fourth insulation layer in the fifteenth via V15 is etched away to expose a surface of the second plate 32 of the storage capacitor. The fifteenth via V15 is configured such that the second electrode of the fourth transistor T4 to be formed subsequently is connected to the second plate 32 of the storage capacitor.

In an exemplary implementation, an orthographic projection of the sixteenth via V16 on the base substrate is within a range of an orthographic projection of the first initial signal line 31 on the base substrate. The fourth insulation layer in the sixteenth via V16 is etched away to expose a surface of the first initial signal line 31. The sixteenth via V16 is configured such that the first electrode of the fourth transistor T4 to be formed subsequently is connected to the first initial signal line 31.

(106) A pattern of a third conductive layer is formed. In an exemplary embodiment, forming the pattern of third conductive layer may include: depositing a third conductive thin film on the base substrate on which the aforementioned patterns are formed, and patterning the third conductive thin film using a patterning process, to form a third conductive layer disposed on the fourth insulation layer, as shown in FIG. 11a and FIG. 11b. FIG. 11a is a diagram of a planar structure of twelve sub-pixels, and FIG. 11b is a schematic plan view of the third conductive layer in FIG. 11a. In an exemplary implementation, the third conductive layer may be referred to as a first source-drain metal (SD1) layer.

In an exemplary implementation, the third conductive layer at least includes a first connection electrode 41, a second connection electrode 42, a third connection electrode 43, a fourth connection electrode 44, a fifth connection electrode 45, a sixth connection electrode 46, a first power supply line 47, a data signal line 48, and a second initial signal line 49.

In an exemplary implementation, the first connection electrode 41 is in a shape of a polyline whose main body portion extends in the second direction Y. A first end of the first connection electrode 41 is connected to the second region 11-2 of the active layer 11 of the first transistor T1 through the second via V2, and is connected to the first plate 25 of the storage capacitor through the eleventh via V11, and a second end the first connection electrode 41 is connected to the second region 12-2 of the second transistor T2 through the fourth via V4, so that the first plate 25, the second electrode of the first transistor T1, and the second electrode of the second transistor T2 have a same potential. In an exemplary embodiment, the first connection electrode 41 may serve as the second electrode of the first transistor T1 and the second electrode of the second transistor T2, so that the second electrode of the first transistor T1 and the second electrode of the second transistor T2 have a same potential.

In an exemplary implementation, the second connection electrode 42 may in a shape of a strip whose main body portion extends in the first direction X. The second connection electrode 42 is connected to the second region 13-2 of the active layer 13 of the third transistor T3 through the fifth via V5, and is connected to the second plate 23 of the storage capacitor through the fourteenth via V14. In an exemplary implementation, the second connection electrode 42 may serve as the second electrode of the third transistor T13, and the second connection electrode 42 is configured such that the second region 13-2 of the active layer 13 of the third transistor T3 is connected to the second plate 23 of the storage capacitor.

In an exemplary implementation, one end of the third connection electrode 43 is connected to the first region 13-1 of the active layer 13 of the third transistor T3 through the sixth via V6, and the other end of the third connection electrode 43 is connected to the second region 15-2 of the active layer 15 of the fifth transistor T5 through the tenth via V10. In an exemplary implementation, the third connection electrode 43 may simultaneously serve as the first electrode of the third transistor T3 and the second electrode of the fifth transistor T5, so that the first electrode of the third transistor T3 and the second electrode of the fifth transistor T5 have a same potential.

In an exemplary implementation, the third connection electrodes 43 of two adjacent rows in the same sub-pixel may be formed into integrated structure. The third connection electrodes 43 in a same sub-pixel group may be connected to the second region 15-2 of the active layer 15 of the same fifth transistor T5 through the tenth vias V10.

In an exemplary implementation, the fourth connection electrode 44 is connected to the second region 14-2 of the active layer 14 of the fourth transistor T4 through the seventh via V7, and the fourth connection electrode 44 is connected to the second plate 32 of the storage capacitor through the fifteenth via V15. In an exemplary implementation, the fourth connection electrode 44 may serve as the second electrode of the fourth transistor T4.

In an exemplary implementation, the fifth connection electrode 45 is connected to the first region 14-2 of the active layer 14 of the fourth transistor T4 through the eighth via V8, and the fifth connection electrode 45 is connected to a first initial signal line 31 in a sub-pixel row through the sixteenth via V16. In an exemplary embodiment, the fifth connection electrode 45 may serve as the first electrode of the fourth transistor T4, and the fifth connection electrode 45 is configured such that the first electrode of the fourth transistor T4 is connected to the first initial signal line 31.

In an exemplary implementation, the sixth connection electrode 46 is connected to the first region 15-1 of the active layer 15 of the fifth transistor T5 through the ninth via V9, and the sixth connection electrode 46 is connected to a first power supply connection line 26 in a sub-pixel row through the twelfth via V13. In an exemplary implementation, the sixth connection electrode 46 may serve as the first electrode of the fifth transistor T5, and is configured to be connected to the first power supply connection line 26.

In an exemplary implementation, sixth connection electrodes 46 of two adjacent rows in a same sub-pixel may be connected to the first region 15-1 of the active layer 15 of the same fifth transistor T5 through the ninth via V9.

In an exemplary implementation, the first power supply line 47 may in a shape of a strip whose main body portion extends in the second direction Y. The first power supply line 47 is connected to a plurality of first power supply connection lines 26 through a plurality of thirteenth vias V13 in a sub-pixel column, so that a first power supply voltage is written to first electrodes of fifth transistors T5 through the first power supply connection lines 26. In the exemplary embodiment, since the first power supply line 47 is connected to all the first power supply connection lines 26 in a sub-pixel column, it is possible to ensure that all the first power supply connection lines 26 (i.e., first electrodes of fifth transistors T5) in a sub-pixel column have a same potential, which is beneficial to improving uniformity of the panel, avoiding poor display of the display substrate, and ensure the display effect of the display substrate.

In an exemplary implementation, the data signal line 48 may have a strip structure whose main body portion extends in the second direction Y. The data signal line 48 is connected to the first region 11-1 of the active layer 11 of the first transistor T1 through the first via V1, and may supply a data signal to the first region 11-1 of the active layer 11 of the first transistor T1. In an exemplary implementation, the data signal line 48 may include a data signal line r connected to a sub-pixel that emits red light, a data signal line g connected to a sub-pixel that emits green light, and a data signal line b connected to a sub-pixel that emits blue light.

In an exemplary implementation, the second initial signal line 49 may have a strip structure whose main body portion extends in the second direction Y. The second initial signal line 49 may be connected to first regions 12-1 of active layers 12 of second transistors T2 in a plurality of rows of sub-pixels through third vias V3, and may provide an initial signal to the active layers of the second transistors T2. In an exemplary implementation, two adjacent columns of pixels may share a second initial signal line 49 to reduce the quantity of traces, save layout space, and thus reduce the width of the bezel.

(107) Patterns of a fifth insulation layer and a first planarization layer are formed. In an exemplary embodiment, forming the patterns of the fifth insulation layer and the first planarization layer may include: first coating a first planarization thin film on the base substrate on which the aforementioned patterns are formed, then depositing a fifth insulation thin film, patterning the first planarization thin film and the fifth insulation thin film using a patterning process, to form a first planarization layer covering the pattern of the third conductive layer and a fifth insulation layer provided on the first planarization layer, wherein the fifth insulation layer and the first planarization layer are provided with a plurality of vias, as shown in FIG. 12a, which is a diagram of a planar structure of twelve sub-pixels.

In an exemplary implementation, a plurality of vias of each sub-pixel at least includes a seventeenth via V17.

In an exemplary implementation, an orthographic projection of the seventeenth via V17 on the base substrate is within a range of an orthographic projection of a fourth connection electrode 44 on the base substrate. The first planarization layer and the fifth insulation layer in the seventeenth via V17 are etched away to expose a surface of the fourth connection electrode 44. The seventeenth via V17 is configured such that an anode connection electrode to be formed subsequently is connected to the fourth connection electrode 44 through the seventeenth via V17.

As shown in FIG. 12b, the fifth insulation layer and the first planarization layer may further be provided with a plurality of first transfer vias Vm1 and a plurality of second transfer vias Vm2.

In an exemplary implementation, an orthographic projection of a first transfer via Vm1 on the base substrate is within a range of an orthographic projection of the data signal line 48 on the base substrate, and the first planarization layer and the fifth insulation layer in the first transfer via Vm1 are etched away to expose a surface of the data signal line 48. The first transfer via Vm1 is configured such that the data signal line 48 is connected to a first transfer connection electrode to be formed subsequently.

In an exemplary implementation, an orthographic projection of a second transfer via Vm2 on the base substrate is within a range of an orthographic projection of the second initial signal line 49 on the base substrate, and the first planarization layer and the fifth insulation layer in the second transfer via Vm2 are etched away to expose a surface of the second initial signal line 49. The second transfer via Vm2 is configured such that the second initial signal line 49 is connected to a second transfer connection electrode to be formed subsequently.

(108) A pattern of a fourth conductive layer is formed. In an exemplary embodiment, forming the pattern of the fourth conductive layer may include: depositing a fourth conductive thin film on the base substrate on which the aforementioned patterns are formed, and patterning the fourth conductive thin film by a patterning process, to form a fourth conductive layer disposed on the fifth insulation layer, as shown in FIG. 13a and FIG. 13b. FIG. 13a is a diagram of a planar structure of twelve sub-pixels, and FIG. 13b is a schematic plan view of the fourth conductive layer in FIG. 13a. In an exemplary implementation, the fourth conductive layer may be referred to as a second source-drain metal (SD2) layer.

In an exemplary embodiment, the fourth conductive layer includes at least first transfer connection electrodes 51, second transfer connection electrodes 52, and anode connection electrodes 53. In an exemplary embodiment, an anode connection electrode 53 is an anode connection electrode of a light emitting element.

In an exemplary embodiment, a first transfer connection electrode 51 may have a strip structure extending in the first direction X, and a plurality of first transfer connection electrodes 51 may be arranged in the second direction Y. As illustrated in FIG. 13c, a plurality of first transfer connection electrodes 51 may be electrically connected to corresponding data signal lines 48 through first transfer vias Vm1.

In an exemplary implementation, a second transfer connection electrode 52 may have a strip structure extending in the first direction X, as shown in FIG. 13c, and a second transfer connection electrode 52 may be electrically connected to the second initial signal line 49 through a second transfer via Vm2.

In an exemplary embodiment, an anode connection electrode 53 may have a strip structure extending in the second direction Y, and an anode connection electrode 51 may be connected to a fourth connection electrode 44 through a seventeenth via V17.

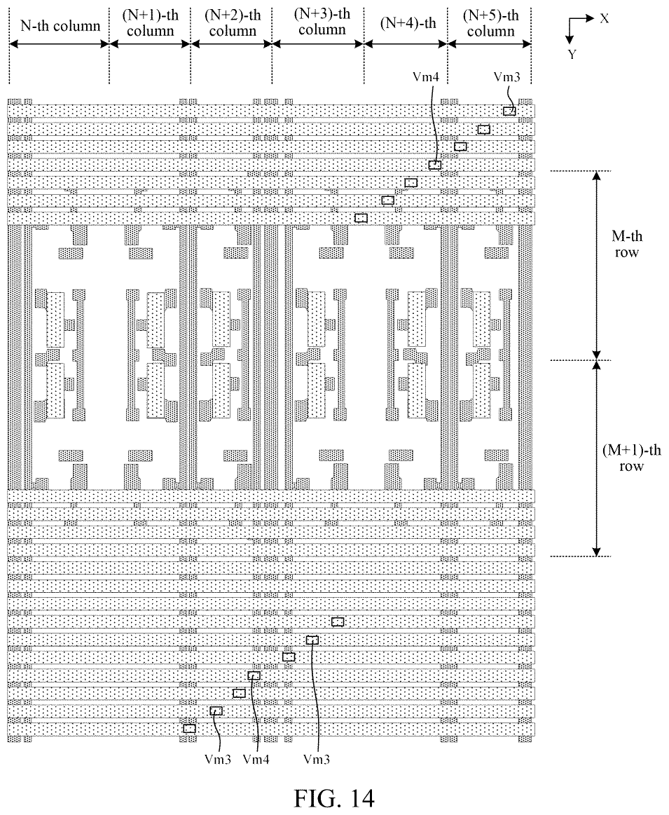

(109) Patterns of a sixth insulation layer and a second planarization layer are formed. In an exemplary embodiment, forming the patterns of the sixth insulation layer and the second planarization layer may include: first coating a second planarization thin film on the base substrate on which the aforementioned patterns are formed, then depositing a sixth insulation thin film, patterning the second planarization thin film and the sixth insulation thin film by a patterning process, to form a second planarization layer covering the pattern of the fourth conductive layer and a sixth insulation layer provided on the second planarization layer, and the sixth insulation layer and the second planarization layer are provided with a plurality of vias, as shown in FIG. 14, which is a diagram of a planar structure of twelve sub-pixels.

In an exemplary implementation, the vias on the sixth insulation layer and the second planarization layer include at least third transfer vias Vm3 and fourth transfer vias Vm4.

In an exemplary implementation, an orthographic projection of a third transfer via Vm3 on the base substrate is within a range of an orthographic projection of a first transfer connection electrode 51 on the base substrate. A third transfer via Vm3 is configured such that a first transfer connection electrode 51 is connected to a third transfer connection electrode to be formed subsequently.

In an exemplary implementation, an orthographic projection of a fourth transfer via Vm4 on the base substrate is within a range of an orthographic projection of a second transfer connection electrode 52 on the base substrate. A fourth transfer via Vm4 is configured such that a second transfer connection electrode 52 is connected to a fourth transfer connection electrode to be formed subsequently.

(110) A pattern of a fifth conductive layer is formed. In an exemplary embodiment, forming the fifth conductive layer may include: depositing a fifth conductive thin film on the base substrate on which the aforementioned patterns are formed, and patterning the fifth conductive thin film by using a patterning process to form a fifth conductive layer provided on the fifth insulation layer, as shown in FIG. 15a and FIG. 15b. FIG. 15a is a diagram of a planar structure of twelve sub-pixels, and FIG. 15b is a schematic plan view of the fifth conductive layer in FIG. 15a. In an exemplary implementation, the fifth conductive layer may be referred to as a second source-drain metal (SD3) layer.

In an exemplary implementation, the fifth conductive layer may include a third transfer connection electrode 61 and a fourth transfer connection electrode 62.

In an exemplary implementation, the third transfer connection electrode 61 and the fourth transfer connection electrode 62 may have a polyline structure extending in the second direction Y, and a plurality of third transfer connection electrodes 61 and a plurality of second transfer connection electrodes 62 may be arranged in the first direction.

In an exemplary implementation, as shown in FIG. 15c, a plurality of third transfer connection electrodes 61 may be respectively connected to a plurality of first transfer connection electrodes 51 through third transfer vias Vm3, and a plurality of fourth transfer connection electrodes 62 may be respectively connected to a plurality of second transfer connection electrodes 52 through fourth transfer vias Vm4.

In an exemplary implementation, orthographic projections of a third transfer connection electrode 61 and a fourth transfer connection electrode 62 on the base substrate are not overlapped with an orthographic projection of an anode connection electrode 53 on the base substrate, so as to avoid occlusion of an anode connection electrode 53 and an anode to be formed subsequently.

In an exemplary implementation, as shown in FIG. 15d, in order to reduce the quantity of traces in the fourth conductive layer and the fifth conductive layer, the signals in second initial signal lines 49 may be led through “pass line” traces, without signal transfer through second transfer connection electrodes 52 in the fourth conductive layer and the fourth transfer connection electrode 62 in the fifth conductive layer, so as to reduce the bezel of the display substrate.

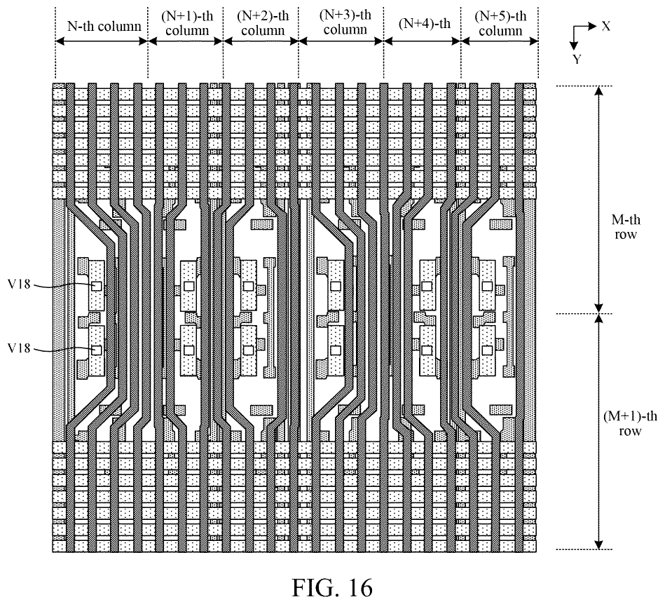

(111) A pattern of a third planarization layer is formed. In an exemplary embodiment, forming the pattern of the third planarization layer may include: coating a third planarization thin film on the base substrate on which the aforementioned patterns are formed, and patterning the third planarization thin film by a patterning process, to form a second planarization layer covering the pattern of the fourth conductive layer and a sixth insulation layer provided on the second planarization layer, wherein the sixth insulation layer and the second planarization layer are provided with a plurality of vias, as shown in FIG. 16, which is a diagram of a planar structure of twelve sub-pixels.

In an exemplary implementation, vias of each sub-pixel at least include an eighteenth via V18.

In an exemplary implementation, an orthographic projection of the eighteenth via V18 on the base substrate is within a range of an orthographic projection of an anode connection electrode 53 on the base substrate. The sixth insulation layer, the second planarization layer and the third planarization layer in the eighteenth via V18 are etched away to expose a surface of the anode connection electrode 53. The eighteenth via V18 is configured such that the anode of the light emitting diode to be formed subsequently is connected to the anode connection electrode 53.

In an exemplary implementation, after the drive circuit layer is prepared, a light emitting structure layer may be prepared on the drive circuit layer, and the preparation process of the light emitting structure layer may include the following operations.

(112) A pattern of an anode conductive layer is formed. In an exemplary implementation, forming the pattern of the anode conductive layer may include: depositing an anode conductive thin film on the base substrate on which the aforementioned patterns are formed, and patterning the anode conductive thin film through a patterning process to form the pattern of the anode conductive layer arranged on the planarization layer, as shown in FIG. 17A and FIG. 17B. FIG. 17B is a schematic plan view of the anode conductive layer in FIG. 17A.

In an exemplary implementation, the anode conductive layer includes at least a plurality of anodes 71.

In an exemplary implementation, an anode 71 is connected to an anode connection electrode 53 through an eighteenth via V18.

In an exemplary implementation, an orthographic projection of the anode 71 on the base substrate may cover an orthographic projection of the anode connection electrode 53 on the base substrate.

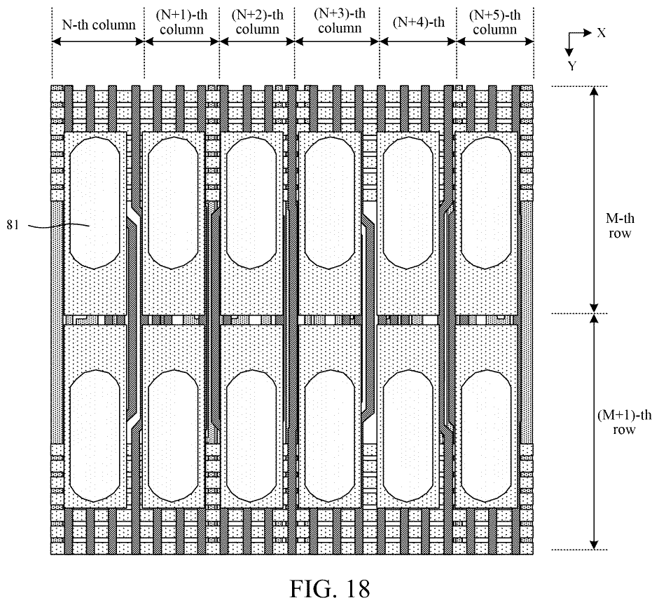

(113) A pattern of a pixel definition layer is formed. In an exemplary implementation, forming the pattern of the pixel definition layer may include: depositing a pixel definition layer thin film on the base substrate on which the aforementioned patterns are formed, and patterning the pixel definition film layer by a patterning process to form a pattern of a pixel definition layer provided on the anode conductive layer, as shown in FIG. 18.

In an exemplary implementation, the pattern of the pixel definition layer may include multiple pixel openings 81, and a pixel opening exposes an anode 71. In an exemplary implementation, an orthographic projection of the pixel opening 81 on the base substrate is within a range of an orthographic projection of the anode 71 on the base substrate.

In an exemplary implementation, a subsequent preparation process may include: forming an organic light emitting layer using an evaporation or inkjet printing process, with the organic light emitting layer being connected to an anode through a pixel opening, and forming a cathode on the organic light emitting layer, wherein the cathode is connected to the organic light emitting layer; forming an encapsulation structure layer, wherein the encapsulation structure layer may include a first encapsulation layer, a second encapsulation layer, and a third encapsulation layer that are stacked. The first encapsulation layer and the third encapsulation layer may be made of an inorganic material, the second encapsulation layer may be made of an organic material, and the second encapsulation layer is arranged between the first encapsulation layer and the third encapsulation layer, so that it may be ensured that external moisture cannot enter the light emitting structure layer.

The display substrate according to the embodiment of the present disclosure are suitable for use as a special-shaped display substrate, and can make shapes of traces in each pixel consistent with each other, thereby avoiding a segment difference of the anode conductive layer caused by inconsistent traces under the anodes, and well avoiding the occurrence of non-uniform light emission due to inconsistent segment differences of anodes. The flatness of the anode conductive layer is determined by two factors: the planarization capability of the planarization layer (PLN), and the flatness of film layers other than the planarization layer below anodes. Usually, the flatness of the planarization layer is better, and it is only necessary to configure the flatness of the film layers other than the planarization layer of a plurality of pixels to be consistent, that is, to keep the traces in a plurality of sub-pixels below the anodes as consistent as possible, so that the segment differences between anodes of the plurality of sub-pixels can be kept consistent as much as possible, and the occurrence of non-uniform light emission due to inconsistent segment differences of anodes can be avoided.

For a special-shaped display substrate, in the fourth conductive layer, a quantity “a” of signal traces extending in the first direction X are provided in space of each row of pixel rows (the signal traces may include at least one of a first transfer connection electrode 51 and a second transfer connection electrode 52 in the fourth conductive layer). In the fifth conductive layer, a quantity “b” of traces extending in the second direction Y are provided in space of each column of pixel columns (the traces may include at least one of a third transfer connection electrode 61 and a fourth transfer connection electrode 62 in the fifth conductive layer). A pixel includes three sub-pixels (i.e., sub-pixels that emit light of three colors: red, green and blue). Three data signal lines 48 respectively connected to the three sub-pixels need to be provided in space of a corresponding column of pixels. For different display driver chips (driver ICs), three cases may be included. In the first case, a second initial signal line 49 may be accessed to the driver IC via a second transfer connection electrode 52 and a fourth transfer connection electrode 62. In this case, the second transfer connection electrode 52 needs to be provided in the fifth conductive layer, and a quantity of signal traces extending in the second direction Y which need to be provided in the space of one column of pixels is 4 (three first transfer connection electrodes 51 corresponding to the three data signal lines and the fourth transfer connection electrode 62 corresponding to one second initial signal line 49). In the second case, if the model of the driver chip does not need to access the second initial signal line 49 via the second transfer connection electrode 52 and the fourth transfer connection electrode 62, the quantity of signal traces extending in the second direction Y which need to be provided in the space of one column of pixels is 3 (the first transfer connection electrodes 51 corresponding to the three data signal lines and the fourth transfer connection electrode 62 corresponding to one second initial signal line 49). In the third case, if two adjacent pixel columns share a second initial signal line 49, the quantity of signal traces extending in the second direction Y which need to be provided in space of one column of pixels is 3.5 (the first transfer connection electrodes 51 corresponding to the three data signal lines and the fourth transfer connection electrode 62 corresponding to 0.5 second initial signal line 49).

In an exemplary implementation, in the fourth conductive layer, the quantity of traces extending in the first direction X is “a” for space of each row of pixels, and in the fifth conductive layer, the quantity of traces extending in the second direction Y is “b” for space of each column of pixels.

If a resolution of the special-shaped display substrate is H*V, the quantity of traces extending in the second direction Y provided on the special-shaped display substrate may be configured to be one of 3H (no need to access the initial signal line 49 to the IC), 3.5H (two pixel columns share a second initial signal line 49), and 4H depending on different models of driver ICs, that is, the value of b may be one of 3, 3.5, and 4. If the quantity of pixels of the special-shaped display substrate close to a Source In side is H/x (x is a ratio of the maximum quantity H of pixel columns of the special-shaped display substrate and the quantity of pixel columns on the Source In side, generally an integer, and its minimum value is 1), there are: b*H/x≥4*H, which can be simplified to b≥4*x. For convenience of illustration, the quantity of traces along the second direction Y in space of one column of pixels can be expressed by a parameter p, then the inequality b*H/x≥4*H can be written as b≥p*x, and the quantity of traces along the second direction Y in space of one column of pixels is the quantity of transfer connection electrodes extending along the second direction Y in one pixel column in the fifth conductive layer. In the exemplary implementation of the present disclosure, the quantity of pixel columns on the Source In side can be understood as the quantity of pixel columns in which the third transfer connection electrodes 61 extend to the bonding region 10 in the display substrate.

For the special-shaped display substrate, the signal traces extending in the first direction X are mainly used to transfer the data signal lines 48 and the second initial signal lines 49 in the third conductive layer to the transfer connection electrodes extending in the first direction X in the fourth conductive layer, and the transfer connection electrodes extending in the second direction Y in the fifth conductive layer are mainly used to transfer the signal traces located in the fourth conductive layer and then access to a driver IC, so that the driver chip (driver IC) provides corresponding driving signals to the data signal lines 48 and corresponding initial signals to the second initial signal lines 49.

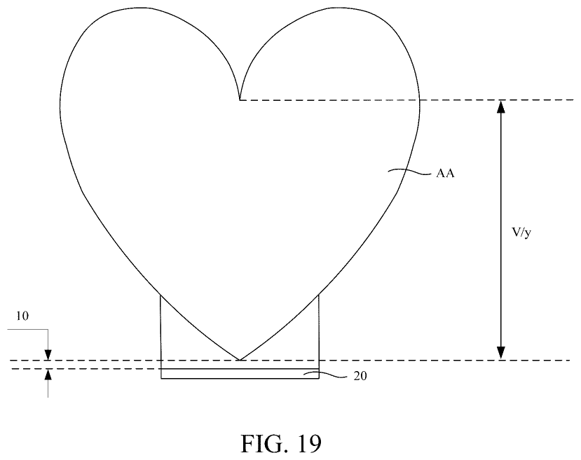

For the special-shaped display substrate having a resolution H*V, among the signal traces in the fourth conductive layer extending along the first direction X, the quantity of signal traces going through a display area AA of the special-shaped display substrate in the first direction X is V/y, where y is a ratio of the maximum row number V of the special-shaped display substrate to the quantity of rows on the Source in side. For the convenience of explanation of y, a heart-shaped display substrate is taken as an example. As shown in FIG. 19, in the fourth conductive layer, there are V/y rows of pixel rows with transfer connection electrodes going through a display area AA of the heart-shaped display substrate. Then the total quantity of transfer connection electrodes in the fourth conductive layer that can transmit signals (which can be understood as effective) is a*V/y. The total quantity of effective traces extending along the first direction X in the fourth conductive layer is consistent with the total quantity of traces extending along the second direction Y in the fifth conductive layer (the traces of the fifth conductive layer are for connecting the effective traces of the fourth conductive layer to the driver chip, so the total quantity of traces in these two conductive layers needs to be consistent). In an actual design process, the total quantity of effective traces extending along the first direction X in the fourth conductive layer is set to be not less than the total quantity of traces extending along the second direction Y in the fifth conductive layer. The total quantity of traces extending along the first direction X in the fourth conductive layer is a*V/y, the total quantity of traces extending along the second direction y in the fifth conductive layer is p*H, and a*V/y≥p*H. After arrangement, we can get that a≥p*y*H/V. In an exemplary implementation of the present disclosure, the quantity of rows on the Source in side can be understood as the quantity of rows of pixels located in a second display area AA2 (that is, transfer connection electrodes in the fourth conductive layer that located in the second display area AA2 can finally access to signals of the driver IC through transfer connection electrodes of the fifth conductive layer).

Considering that the quantities of a and b are both integers, and for the subsequent connection of the fourth conductive layer with the third conductive layer through vias, and the connection of the fifth conductive layer with the fourth conductive layer through vias, the value of p can be set to a common divisor of a and b, herein p may be a decimal (for example, p=3.5 when a second initial signal line is shared by two columns of pixels), which needs to be calculated according to 2p, so the values of a and b can be reduced by reducing the value of p as much as possible. Considering the principle of minimizing a and b, the values of a and b can be obtained according to the above analysis:

$$a = [ y * H / V ] * p ; b = [ x ] * p ;$$

If 2p is an integer and p is a decimal, the above formula can be written as: 2a=[y*H/V]*2p; 2b=[x]*2p. Taking a heart-shaped display substrate with a resolution of H*V, i.e. of 1440*1440, as an example, set p=3.5, y=1, and x=3, and bring H=1440 and V=1440 into the above formula to obtain 2a=14, 2b=21, and a corresponding schematic diagram of the planar structure of the display substrate can be shown in FIG. 15a.

In an implementation of the present disclosure, the quantity of traces a in the fourth conductive layer and the quantity of traces b in the fifth conductive layer are directly related to the value of p, and the second initial signal line 49 can reduce the value of p by a Pass line mode. Then set P=3, y=1, x=3, and bring H=1440, V=1440 into the above formula to obtain 2a=12, 2b=18. A corresponding schematic diagram of the planar structure of the display substrate can be shown in FIG. 15d. In the structure shown in FIG. 15d, a second initial signal line 49 does not provide a signal through the driver IC, but through a signal path of a Chip On Film (abbreviated as COF) (the mode of the second initial signal line 49 providing a signal not through the IC chip but through the COF can be referred to as a Pass line), which reduces the quantity of traces in the fourth conductive layer and the fifth conductive layer (reducing the second transfer connection electrodes 52 in the fourth conductive layer and the fourth transfer connection electrodes 62 in the fifth conductive layer).

In an exemplary implementation, the data signal lines 49 of three sub-pixels in one pixel can be combined according to the shape of the display substrate (this design mode can be referred to as a Triple gate principle), which can reduce the quantity of traces in the fourth conductive layer and the fifth conductive layer (that is, can reduce the value of p). In this design scheme, p=1, a=2, b=3, that is, the space of each row of pixels is provided with two first transfer connection electrodes extending in the first direction X in the fourth conductive layer, and the space of each column of pixels is provided with three third transfer connection electrodes 61 extending in the second direction Y in the fifth conductive layer.

In an exemplary implementation, for the special-shaped display substrate, as shown in FIGS. 12b, 13c, 14, and 15c, the third conductive layer is electrically connected to the fourth conductive layer through first transfer vias Vm1, and the fourth conductive layer is electrically connected to the fifth conductive layer through third transfer vias Vm3 and fourth transfer vias Vm4. A first transfer via Vm1 to a fourth transfer via Vm4 are not provided in every pixel, but the positions for setting transfer vias are determined according to the shape of the special-shaped display substrate, which can ensure that all data signal lines and initial signal lines are connected to the bonding area 10 of the display substrate through traces in the fourth conductive layer and the fifth conductive layer. The traces in the fifth conductive layer can be electrically connected to a drive device 20 through the bonding area 10. The drive device 20 may include at least one of a COF and an IC chip. For a heart-shaped display substrate, the provided positions of the first to fourth vias may be as shown in FIG. 21. The arrangement direction of first transfer vias Vm1 and second transfer vias Vm2 in the display area AA may be a first included angle F1 with a center line Q1-Q1 extending in the second direction Y of the display substrate, and the arrangement direction of the third transfer vias Vm3 to the fourth transfer vias Vm4 may be a second included angle F2 with the center line Q1-Q1 extending in the second direction Y of the display substrate. For a heart-shaped display substrate, a value of the first included angle F1 may be 45 degrees. Affected by the shape of the special-shaped display substrate, the fourth conductive layer needs to transfer the signals of all the data signal lines and the second initial signal lines in the third conductive layer to the transfer connection electrodes of the fourth conductive layer. The transfer vias are usually designed according to a pitch between the sub-pixels, that is, the arrangement direction of a plurality of transfer vias is substantially 45 degrees. However, affected by the special-shaped screen, this direction cannot transfer all the data signal lines and the transfer connection electrodes of the third conductive layer to the fourth conductive layer. Therefore, a part of the transfer vias may be moved into the display area AA of the display substrate in a vertical direction (the first direction X or an opposite direction of the first direction X in FIG. 21), thereby forming an arrangement of two parts, i.e. upper and lower parts, of transfer vias as shown in FIG. 21.

In an exemplary implementation, the fourth conductive layer may be further provided with a second power supply line, the display substrate may further include a bezel area 30, and the second power supply line VSS may be located in the bezel area 30. As shown in FIG. 22, the second power line VSS located in the fourth conductive layer may be electrically connected to the fourth conductive layer in the display area through a second power supply connection line 50. The second power supply line VSS may be composed of a double-layer structure of a third conductive layer and a fourth conductive layer. The double-layer structure may reduce a voltage drop of the second power supply line VSS. Since the fourth conductive layer is provided with the second power supply line VSS, the second power supply line VSS may be directly electrically connected to the fourth conductive layer located in the display area AA. In FIG. 22, reference numeral 40 denotes an encapsulation structure region, and reference numeral 60 denotes an initial signal line.

An embodiment of the present disclosure further provides a display apparatus, including the display substrate described above. The display apparatus may be any product or component with a display function such as a mobile phone, a tablet computer, a television, a display, a laptop computer, a digital photo frame, and a navigator.

In a display substrate and a display apparatus according to an embodiment of the present disclosure, a display area in the display substrate includes a plurality of data signal lines, a plurality of first transfer connection electrodes, a plurality of third transfer connection electrodes, and a plurality of sub-pixels arranged in an array. At least a part of the first transfer connection electrodes are respectively electrically connected to the plurality of data signal lines, and are respectively electrically connected to at least a part of the third transfer connection electrodes. One ends of the third transfer connection electrodes connected to the at least part of the first transfer connection electrodes are electrically connected to the bonding area. In the display area, the lengths of the plurality of data signal lines along the second direction are not identical. The plurality of sub-pixels form a plurality of pixels arranged in an array, a pixel includes at least three adjacent sub-pixels, and the arrangement modes of a plurality of first transfer connection electrodes and a plurality of third transfer connection electrodes located in two pixels are consistent. In the display substrate according to the embodiment of the present disclosure, the arrangement modes of the plurality of first transfer connection electrodes and the plurality of third transfer connection electrodes located in two pixels are consistent, so that the segment differences of anodes in the plurality of pixels are consistent, which can effectively avoid occurrences of non-uniform light emission. In the display substrate according to the embodiment of the present disclosure, the lengths of the plurality of data signal lines along the second direction in the display area are not identical, so that the display substrate can be suitable for use as a special-shaped display substrate, and that the non-uniform light emission of the special-shaped display substrate due to inconsistent segment differences of anodes can be avoided.

Although the implementations disclosed in the embodiments of the present disclosure are described above, the described contents are only implementations used for facilitating understanding of the embodiments of the present disclosure, but are not intended to limit the present disclosure. Any of those skilled in the art of the present disclosure can make any modifications and variations in the implementation and details without departing from the spirit and scope of the present disclosure. However, the protection scope of the present disclosure should be subject to the scope defined by the appended claims.

1. A display substrate, comprising a display area and a bonding area connected to the display area, wherein the display area comprises a plurality of data signal lines extending in a second direction, a plurality of first transfer connection electrodes extending in a first direction, a plurality of third transfer connection electrodes extending in the second direction, and a plurality of sub-pixels arranged in an array, the plurality of data signal lines are respectively connected to a plurality of columns of sub-pixels, and the data signal lines, the first transfer connection electrodes, and the third transfer connection electrodes are respectively arranged in three conductive layers;
at least a part of the first transfer connection electrodes are respectively electrically connected to the plurality of data signal lines and respectively electrically connected to at least a part of the third transfer connection electrodes, and one ends of the third transfer connection electrodes connected to the at least part of the first transfer connection electrodes are electrically connected to the bonding area; in the display area, lengths of the plurality of data signal lines along the second direction are not the same; and
the plurality of sub-pixels form a plurality of pixels arranged in an array, wherein one of the pixels comprises at least three adjacent sub-pixels, and arrangement modes of a plurality of first transfer connection electrodes and a plurality of third transfer connection electrodes located in two pixels are consistent.

2. The display substrate of claim 1, wherein the display area comprises a first display area and a second display area, a plurality of first transfer connection electrodes located in the second display area go through the second display area in the first direction, at least a part of the first transfer connection electrodes located in the second display area are electrically connected to the plurality of data signal lines respectively, and a plurality of first transfer connection electrodes located in the first display area do not go through the first display area of the display substrate in the first direction; at least a part of the third transfer connection electrodes are electrically connected to the plurality of first transfer connection electrodes located in the second display area, respectively; and
arrangement modes of first transfer connection electrodes, third transfer connection electrodes and data signal lines in pixels located in the first display area are consistent with arrangement modes of first transfer connection electrodes, third transfer connection electrodes and data signal lines in the pixels located in the second display area.

3. The display substrate of claim 2, further comprising a plurality of second initial signal lines extending in the second direction, a plurality of second transfer connection electrodes extending in the first direction, and a plurality of fourth transfer connection electrodes extending in the second direction, wherein the second initial signal lines are provided in a same layer as the plurality of data signal lines, the plurality of second transfer connection electrodes are provided in a same layer as the plurality of first transfer connection electrodes, and the plurality of fourth transfer connection electrodes are provided in a same layer as the plurality of third transfer connection electrodes; and
a plurality of second transfer connection electrodes located in the second display area going through the second display area of the display substrate in the first direction and are electrically connected to the plurality of second initial signal lines respectively, and a plurality of second transfer connection electrodes located in the first display area not going through the first display area of the display substrate in the first direction; at least a part of the fourth transfer connection electrodes are electrically connected to the plurality of second transfer connection electrodes located in the second display area respectively.

4. The display substrate of claim 3, wherein one pixel comprises three sub-pixels, three columns of sub-pixels and three data signal lines are provided in space of a same column of pixels, the three columns of sub-pixels are respectively connected to the three data signal lines, two adjacent columns of pixels share one second initial signal line, and the second initial signal line is located between the two adjacent columns of pixels; twenty third transfer connection electrodes and one fourth transfer connection electrode are provided in space of two columns of pixels which share a second initial signal line, ten third transfer connection electrodes are provided in space of each column of pixels, and one fourth transfer connection electrode is located between the two columns of pixels; and
six first transfer connection electrodes and one second transfer connection electrode are provided in space of a same row of pixels.

5. The display substrate of claim 2, wherein one of the pixels comprises three sub-pixels, three columns of sub-pixels, three data signal lines, and nine third transfer connection electrodes are provided in space of a same column of pixels, and the three columns of sub-pixels are respectively connected to the three data signal lines; and six first transfer connection electrodes are provided in space of a same row of pixels.

6. The display substrate of claim 2, wherein one of the pixels comprises three sub-pixels, three columns of sub-pixels, three data signal lines, and three third transfer connection electrodes are provided in space of a same column of pixels, and the three columns of sub-pixels are respectively connected to the three data signal lines; and two first transfer connection electrodes are provided in space of a same row of pixels.

7. The display substrate of claim 1, wherein one of the sub-pixels comprises a first transistor to a fifth transistor and a storage capacitor, and the second transistor, the first transistor, the third transistor, the fourth transistor, and the fifth transistor are arranged in the second direction on a plane parallel to the display substrate; an orthographic projection of the storage capacitor on a base substrate is overlapped with an orthographic projection of the third transistor on the base substrate; and
in a same pixel, two adjacent sub-pixels are symmetrically provided with respect to a first center line, and the first center line is a center line of the two adjacent sub-pixels extending in the second direction.

8. The display substrate of claim 7, wherein a plurality of sub-pixel groups are comprised in a same column of sub-pixels, each sub-pixel group comprises two adjacent sub-pixels, and two sub-pixels in a same sub-pixel group share a fifth transistor.

9. The display substrate of claim 2, wherein at least one sub-pixel comprises a pixel drive circuit, and the pixel drive circuit comprises a plurality of oxide transistors and a storage capacitor;
in a plane perpendicular to the display substrate, the display substrate comprises a base substrate and a semiconductor layer, a first conductive layer, a second conductive layer, a third conductive layer, a fourth conductive layer, and a fifth conductive layer which are sequentially stacked on the base substrate;
the semiconductor layer comprises active layers of the plurality of oxide transistors.
the first conductive layer comprises control electrodes of the plurality of oxide transistors and a first plate of the storage capacitor;
the second conductive layer comprises a second plate of the storage capacitor.
the third conductive layer comprises the plurality of data signal lines, and first electrodes and second electrodes of the plurality of oxide transistors;
the fourth conductive layer comprises the plurality of first transfer connection electrodes; and
the fifth conductive layer comprises the plurality of third transfer connection electrodes.

10. The display substrate of claim 9, wherein the third conductive layer further comprises a plurality of second initial signal lines extending in the second direction; two adjacent columns of pixels share one of the second initial signal lines, and a plurality of data signal lines in two columns of pixels which share one second initial signal line are symmetrical with respect to the second initial signal line;
the fourth conductive layer further comprises a plurality of second transfer connection electrodes extending in the first direction, and a plurality of second transfer connection electrodes located in the second display area are electrically connected to the plurality of second initial signal lines respectively; and
the fifth conductive layer further comprises a plurality of fourth transfer connection electrodes extending in the second direction; the plurality of fourth transfer connection electrodes are electrically connected to a plurality of second transfer connection electrodes located in the second display area respectively.

11. The display substrate of claim 9, wherein the display substrate is heart-shaped, the bonding area is located on one side of the display area, and the first display area, the second display area, and the bonding area are sequentially arranged in the second direction.

12. The display substrate of claim 11, wherein the at least part of the first transfer connection electrodes are respectively electrically connected to the plurality of data signal lines through a plurality of first transfer vias, the at least part of the third transfer connection electrodes are respectively electrically connected to the at least part of the first transfer connection electrodes through a plurality of third transfer vias, a first included angle is formed between an arrangement direction of the plurality of first transfer vias and a center line of the display substrate extending in the second direction, and a second included angle is formed between an arrangement direction of the plurality of third transfer vias and the center line of the display substrate extending in the second direction.

13. The display substrate of claim 12, wherein the first included angle ranges from 30 degrees to 60 degrees, and the second included angle ranges from 15 degrees to 45 degrees.

14. The display substrate of claim 12, wherein the arrangement direction of the plurality of first transfer vias is provided symmetrically with respect to the center line of the display substrate extending in the second direction, and the arrangement direction of the plurality of third transfer vias is provided symmetrically with respect to the center line of the display substrate extending in the second direction.

15. The display substrate of claim 14, wherein in the display area located on one side of the center line of the display substrate extending in the second direction, a plurality of first transfer vias are arranged in at least two directions, and the at least two arrangement directions are parallel to each other, and connection lines of a plurality of first transfer vias located in the at least two arrangement directions are arranged in the second direction; a plurality of third transfer vias are arranged along at least two directions, and the at least two arrangement directions are parallel to each other, and connection lines of a plurality of third transfer vias located in the at least two arrangement directions are arranged along the second direction.

16. The display substrate of claim 8, wherein the fourth conductive layer further comprises anode connection electrodes respectively electrically connected to a plurality of sub-pixels, and orthographic projections of the first transfer connection electrodes and the third transfer connection electrodes on the base substrate are not overlapped with orthographic projections of the plurality of anode connection electrodes on the base substrate.

17. The display substrate of claim 16, further comprising an anode conductive layer, wherein the anode conductive layer comprises a plurality of anodes respectively connected to the plurality of anode connection electrodes; there is a first overlapping region between orthographic projections of a plurality of anodes in a same pixel on the base substrate and orthographic projections of the plurality
of first transfer connection electrodes and the plurality of third transfer connection electrodes on the base substrate, the plurality of pixels correspond to a plurality of first overlapping regions, and areas of the plurality of first overlapping regions are consistent.

18. The display substrate of claim 1, wherein a size of the bonding region in the first direction is smaller than a size of the display area in the first direction, and the plurality of third transfer connection electrodes comprise two parts, with a part extending to the bonding region and a part not extending to the bonding region, and wherein a plurality of third transfer connection electrodes extending to the bonding region are electrically connected to a plurality of first transfer connection electrodes located in the second display area, respectively.

19. A display apparatus, comprising the display substrate according to claim 1.

20. The display substrate of claim 2, wherein one of the sub-pixels comprises a first transistor to a fifth transistor and a storage capacitor, and the second transistor, the first transistor, the third transistor, the fourth transistor, and the fifth transistor are arranged in the second direction on a plane parallel to the display substrate; an orthographic projection of the storage capacitor on a base substrate is overlapped with an orthographic projection of the third transistor on the base substrate; and
in a same pixel, two adjacent sub-pixels are symmetrically provided with respect to a first center line, and the first center line is a center line of the two adjacent sub-pixels extending in the second direction.
